(19) United States
(12) Patent Application Publication
(10) Pub. No.: US 2023/0171945 A1
(43) Pub. Date: Jun. 1, 2023

(54) SEMICONDUCTOR MEMORY DEVICE AND MANUFACTURING METHOD OF SEMICONDUCTOR MEMORY DEVICE

(71) Applicant: Unisantis Electronics Singapore Pte. Ltd., Singapore (SG)

(72) Inventors: Nozomu Harada, Tokyo (JP); Koji Sakui, Tokyo (JP)

(21) Appl. No.: 17/994,650

(22) Filed: Nov. 28, 2022

(30) Foreign Application Priority Data
Nov. 29, 2021 (JP) PCT/JP2021/043596

(51) Int. Cl. H01L 27/108

(52) U.S. Cl. CPC H01L 27/10802

(57) ABSTRACT

A Si pillar is formed in a memory region. A TiN layer to be connected to a plate line and a TiN layer to be connected to a word line are formed to extend in a horizontal direction, bend upward from the horizontal direction to a vertical direction in a memory region peripheral portion, and have upper surfaces on a same plane. The TiN layers are connected to metal wiring layers via contact holes formed on the upper surfaces thereof. A memory operation is performed by storing or not storing a group of holes generated by an impact ionization phenomenon in the Si pillar by controlling voltages to be applied to a source line, the plate line, the word line, and a bit line.

### CROSS-REFERENCE TO RELATED APPLICATIONS

This application claims priority to PCT/JP2021/043596, filed Nov. 29, 2021, the entire content of which is incorporated herein by reference.

### BACKGROUND OF THE INVENTION

### 1. Field of the Invention

The present invention relates to a semiconductor memory device and a manufacturing method of the semiconductor memory device.

### 2. Description of the Related Art

In recent years, there has been a demand for a memory element having a higher degree of integration and a higher performance in the development of the large scale integration (LSI) technology.

Typical planar metal-oxide-semiconductor (MOS) transistors have a channel that extends in a horizontal direction along the upper surface of a semiconductor substrate. In contrast, surrounding gate transistors (SGTs) have a channel that extends in a direction perpendicular to the upper surface of a semiconductor substrate (refer to, for example, Japanese Unexamined Patent Application Publication No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). For this reason, SGTs enable an increase in the density of semiconductor devices compared with planar MOS transistors. Such SGTs can be used as selection transistors to achieve a higher degree of integration of a dynamic random access memory (DRAM) (refer to, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)) to which a capacitor is connected, a phase change memory (PCM) (refer to, for example, H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No. 12, December, pp. 2201-2227 (2010)) to which a resistance-change element is connected, a resistive random access memory (RRAM) (refer to, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3V,” IEDM (2007)), a magneto-resistive random access memory (MRAM) (refer to, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)) in which the orientation of magnetic spins is changed with a current to change the resistance, and the like. Furthermore, there is a DRAM memory cell (refer to M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)) that is constituted by a single MOS transistor and that includes no capacitor. The present application relates to a dynamic flash memory that can be constituted only by a MOS transistor and that includes neither a resistance-change element nor a capacitor.

FIGS. 8A to 8D illustrate a write operation of the above-mentioned DRAM memory cell constituted by a single MOS transistor and including no capacitor, FIGS. 9A and 9B illustrate a problem in the operation thereof, and FIGS. 10A to 10C illustrate a read operation thereof.

FIGS. 8A to 8D illustrate the write operation of the DRAM memory cell. FIG. 8A illustrates a “1” write state. Here, the memory cell is formed in a silicon on insulator (SOI) substrate 100 and constituted by a source N⁺ layer 103 (hereinafter, a semiconductor region including a donor impurity at a high concentration will be referred to as “N⁺ layer”) to which a source line SL is connected, a drain N⁺ layer 104 to which a bit line BL is connected, a gate conductor layer 105 to which a word line WL is connected, and a floating body 102 of a memory cell 110a, which is a MOS transistor. The DRAM memory cell is constituted by the single memory cell 110a and includes no capacitor. Note that a SiO₂ layer 101 of the SOI substrate is in contact with the floating body 102 directly under the floating body 102. At the time of writing “1” in the memory cell constituted by the single memory cell 110a, the memory cell 110a is operated in the saturation region. That is, a channel 107 for electrons extending from the source N⁺ layer 103 has a pinch-off point 108 and does not reach the drain N⁺ layer 104 to which the bit line BL is connected. In this manner, when both the bit line BL connected to the drain N⁺ layer 104 and the word line WL connected to the gate conductor layer 105 are set at high voltages, and the memory cell 110a is operated at a gate voltage that is about ½ of the drain voltage, the electric field strength becomes maximum at the pinch-off point 108 near the drain N⁺ layer 104. As a result, accelerated electrons flowing from the source N⁺ layer 103 toward the drain N⁺ layer 104 collide with the lattice of Si, and electron-hole pairs are generated by the kinetic energy lost at this time (impact ionization phenomenon). Most of the generated electrons (not illustrated) reach the drain N⁺ layer 104. Only a small number of very hot electrons jump over a gate oxide film 109 and reach the gate conductor layer 105. Holes 106 that have been generated at the same time charge the floating body 102. In this case, the generated holes 106 contribute to an increment of the majority carrier because the floating body 102 is P-type Si. When the floating body 102 is filled with the generated holes 106 and the voltage of the floating body 102 becomes higher than that of the source N⁺ layer 103 by Vb or more, holes that are further generated are discharged to the source N⁺ layer 103. Here, Vb is a built-in voltage of the PN junction between the floating body 102 of a P layer and the source N⁺ layer 103, and is about 0.7 V. FIG. 8B illustrates a state in which the floating body 102 is charged to saturation with the generated holes 106.

Next, a “0” write operation of a memory cell 110b will be described with reference to FIG. 8C. The memory cell 110a in which “1” is written and the memory cell 110b in which “0” is written are present at random with respect to a common selected word line WL. FIG. 8C illustrates a state in which a “1” write state is rewritten to a “0” write state. At the time of writing “0”, the voltage of the bit line BL is set to a negative bias, and the PN junction between the floating body 102 of the P layer and the drain N⁺ layer 104 is forward biased. As a result, the holes 106 that are generated in advance in the floating body 102 in the previous cycle flow into the drain N⁺ layer 104 connected to the bit line BL. Upon completion of the write operation, a state of two memory cells, which are the memory cell 110a filled with the generated holes 106 (FIG. 8B) and the memory cell 110b in which the generated holes 106 are discharged (FIG. 8C), is obtained. The potential of the floating body 102 of the memory cell 110a filled with the holes 106 becomes higher than that of the floating body 102 in which the generated holes 106 are not present. Accordingly, the threshold voltage of the memory cell 110a becomes lower than the threshold voltage of the memory cell 110b. This state is illustrated in FIG. 8D.

Next, a problem in the operation of the memory cell constituted by the single MOS transistor will be described with reference to FIGS. 9A and 9B. As illustrated in FIG. 9A, a capacitance C_{FB} of the floating body 102 is the sum of a capacitance C_{WL}, a junction capacitance C_{BL}, and a junction capacitance C_{SL}. The capacitance C_{WL} is a capacitance between the floating body 102 and the gate to which the word line WL is connected. The junction capacitance C_{BL} is a capacitance of the PN junction between the floating body 102 and the drain N⁺ layer 104 to which the bit line BL is connected. The junction capacitance C_{SL} is a capacitance of the PN junction between the floating body 102 and the source N⁺ layer 103 to which the source line SL is connected. The capacitance C_{FB} is expressed as follows.

C_{FB}=C_{WL}+C_{BL}+C_{SL} (1)

Accordingly, when a word line voltage V_{WL} swings at the time of writing, the voltage of the floating body 102 serving as a storage node (contact point) of the memory cell is also affected by this swing. This state is illustrated in FIG. 9B. When the word line voltage V_{WL} increases from 0 V to V_{ProgWL} at the time of writing, a voltage V_{FB} of the floating body 102 increases from a voltage V_{FB1} in the initial state before the change in the word line voltage V_{WL} to V_{FB2} by a capacitive coupling with the word line WL. A voltage change amount ΔV_{FB} is expressed as follows.

$${ΔV}_{FB} = {V}_{FB 2} - {V}_{FB 1} = {C}_{WL} / ( {C}_{WL} + {C}_{BL} + {C}_{SL} ) \times {V}_{ProgWL} \qquad ( 2 )$$

Here, β is a coupling ratio and is expressed as follows.

β=C_{WL}/(C_{WL}+C_{BL}+C_{SL}) (3)

In such a memory cell, C_{WL} has a large contribution ratio, and, for example, C_{WL}:C_{BL}:C_{SL}=8:1:1. In this case, β=0.8. When the voltage of the word line WL changes, for example, from 5 V at the time of writing to 0 V after completion of writing, the floating body 102 is subjected to a swing noise of as large as 5 V×β=4 V due to the capacitive coupling between the word line WL and the floating body 102. Accordingly, there has been a problem in that a potential difference margin is not provided sufficiently between the “1” potential and the “0” potential of the floating body 102 at the time of writing.

FIGS. 10A to 10C illustrate a read operation. FIG. 10A illustrates the “1” write state, and FIG. 10B illustrates the “0” write state. Actually, however, even if Vb is written in the floating body 102 in “1” writing, when the voltage of the word line WL returns to 0 V upon the completion of writing, the floating body 102 is lowered to a negative bias. Since writing of “0” brings a deeper negative bias, as illustrated in FIG. 10C, it is not possible to make the potential difference margin between “1” and “0” sufficiently large at the time of writing. This small operation margin has been a major problem for the DRAM memory cell. In addition, the density of the memory cell needs to be increased. Furthermore, the external connection of wiring electrodes of the memory cell needs to be simplified.

### SUMMARY OF THE INVENTION

In a capacitor-less single-transistor DRAM (gain cell) in a memory device using an SGT, the capacitive coupling between a word line and an SGT body in the floating state is large, and there has been a problem in that, when the potential of the word line is made to swing at the time of reading or writing of data, the swing is directly transmitted as noise to the SGT body. This results in a problem of reading error or rewriting error of storage data and makes it difficult to put a capacitor-less single-transistor DRAM (gain cell) into practical use. It is necessary not only to solve the above problem but also to achieve a higher performance and density of the DRAM memory cell.

To solve the above problem, an aspect of the present invention is a manufacturing method of a semiconductor memory device that performs a data retention operation and a data erase operation, the data retention operation being an operation in which voltages to be applied to a first gate conductor layer, a second gate conductor layer, a first impurity layer, and a second impurity layer are controlled to retain, inside a semiconductor pillar, a group of holes or electrons that are generated by an impact ionization phenomenon or a gate induced drain leakage current and that serve as majority carriers in the semiconductor pillar, and the data erase operation being an operation in which the voltages to be applied to the first gate conductor layer, the second gate conductor layer, the first impurity layer, and the second impurity layer are controlled to discharge, from the semiconductor pillar, the group of holes or electrons that serve as majority carriers in the semiconductor pillar, the manufacturing method including:

a step of defining, on a substrate, a memory region in which a plurality of semiconductor pillars each of which is the semiconductor pillar are formed two-dimensionally, a first memory region peripheral portion that is on an outer side of the memory region, and an outer region that is on an outer side of and is adjacent to the first memory region peripheral portion;

a step of forming, on the substrate in the outer region, a peripheral material layer having
an upper surface at a position higher than an upper surface of the first memory region peripheral portion, and
a step-like shape at a boundary with the first memory region peripheral portion;

a step of forming, on the substrate in the memory region, the first impurity layer and a first insulating layer;

a step of forming, in the memory region and the first memory region peripheral portion and on the peripheral material layer, from a bottom, the first gate conductor layer, a second insulating layer, the second gate conductor layer, and a third insulating layer such that the first gate conductor layer, the second insulating layer, the second gate conductor layer, and the third insulating layer have a shape that is substantially same as the step-like shape between the first memory region peripheral portion and the peripheral material layer and that at least an upper surface of the third insulating layer in the memory region is positioned lower than the upper surface of the peripheral material layer;

a step of making, in the first memory region peripheral portion, the first gate conductor layer and the second gate conductor layer bend upward in a vertical direction along the step-like shape, making the first gate conductor layer and the second gate conductor layer have upper surfaces at a same position, and making the upper surfaces of the first gate conductor layer and the second gate conductor layer positioned close to the upper surface of the peripheral material layer; and

a step of forming a first metal wiring layer to be connected to the first gate conductor layer and a second metal wiring layer to be connected to the second gate conductor layer in the first memory region peripheral portion (first invention).

In the first invention, the manufacturing method further includes:

a step of, after forming the peripheral material layer and the first insulating layer, forming, from the bottom, a first material layer, the second insulating layer, a second material layer, and the third insulating layer such that the first material layer, the second insulating layer, the second material layer, and the third insulating layer cover the memory region, the first memory region peripheral portion, and the outer region;

a step of polishing an entirety of the memory region, the first memory region peripheral portion, and the outer region such that, in the first memory region peripheral portion, upper surfaces of the first material layer, the second insulating layer, the second material layer, and the third insulating layer, which extend in the vertical direction, are positioned close to the upper surface of the peripheral material layer;

a step of forming, on the first impurity layer in the memory region, a first hole penetrating through the third insulating layer, the second material layer, the second insulating layer, the first material layer, and the first insulating layer in the vertical direction;

a step of forming the semiconductor pillar embedded in the first hole;

a step of removing the first material layer to form a second hole and removing the second material layer to form a third hole;

a step of forming a first gate insulating layer inside the second hole and forming a second gate insulating layer inside the third hole; and

a step of forming a first conductor layer that is embedded in the second hole to serve as the first gate conductor layer and a second conductor layer that is embedded in the third hole to serve as the second gate conductor layer (second invention).

In the second invention, the manufacturing method further includes: a step of, before forming the second hole and the third hole, forming a fourth insulating layer that is connected to the second insulating layer and the third insulating layer in the first memory region peripheral portion and that extends from an upper surface of the first insulating layer in the vertical direction such that an upper surface of the fourth insulating layer is positioned close to the upper surface of the peripheral material layer (third invention).

In the first invention, the manufacturing method further includes

a step of, after forming the peripheral material layer and the first insulating layer, forming, from the bottom, a third conductor layer that is to serve as the first gate conductor layer, the second insulating layer, a fourth conductor layer that is to serve as the second gate conductor layer, and the third insulating layer such that the third conductor layer, the second insulating layer, the fourth conductor layer, and the third insulating layer cover the memory region, the first memory region peripheral portion, and the outer region;

a step of polishing an entirety of the memory region, the first memory region peripheral portion, and the outer region such that, in the first memory region peripheral portion, upper surfaces of the third conductor layer, the second insulating layer, the fourth conductor layer, and the third insulating layer, which extend in the vertical direction, are positioned close to the upper surface of the peripheral material layer;

a step of forming, in the memory region, a fourth hole penetrating through the third insulating layer, the fourth conductor layer, the second insulating layer, the third conductor layer, and the first insulating layer; and

a step of forming a third gate insulating layer that covers an inner wall of the fourth hole and the semiconductor pillar that is in contact with the first impurity layer (fourth invention).

In the first invention, in a second memory region peripheral portion opposite to the first memory region peripheral portion with the memory region therebetween in plan view, the second insulating layer that bends from a horizontal direction to the vertical direction is not formed (fifth invention).

In the first invention, if one of the first impurity layer and the second impurity layer is connected to a source line, another of the first impurity layer and the second impurity layer is connected to a bit line, and if one of the first gate conductor layer and the second gate conductor layer is connected to a plate line, another of the first gate conductor layer and the second gate conductor layer is connected to a word line (sixth invention).

In the first invention, the manufacturing method further includes

a step of forming a third material layer on the third insulating layer;

a step of removing part of the third material layer to expose a top portion of the semiconductor pillar; and

a step of forming the second impurity layer that covers the exposed top portion of the semiconductor pillar or that is inside the top portion (seventh invention).

In the first invention, the third insulating layer is formed of a plurality of material layers (eighth invention).

To solve the above problem, another aspect of the present invention is a semiconductor memory device in which each of memory cells performs a data retention operation and a data erase operation, the data retention operation being an operation in which voltages to be applied to a first gate conductor layer, a second gate conductor layer, a first impurity layer, and a second impurity layer are controlled to retain, inside a semiconductor pillar, a group of holes or electrons that are generated by an impact ionization phenomenon or a gate induced drain leakage current and that serve as majority carriers in the semiconductor pillar, and the data erase operation being an operation in which the voltages to be applied to the first gate conductor layer, the second gate conductor layer, the first impurity layer, and the second impurity layer are controlled to discharge, from the semiconductor pillar, the group of holes or electrons that serve as majority carriers in the semiconductor pillar, the semiconductor memory device including:

on a substrate, a memory region in which a plurality of semiconductor pillars each of which is the semiconductor pillar are formed two-dimensionally, a first memory region peripheral portion that is on an outer side of the memory region, and an outer region that is on an outer side of and is adjacent to the first memory region peripheral portion;

on the substrate in the outer region, a peripheral material layer having
an upper surface at a position higher than an upper surface of the first memory region peripheral portion, and
a step-like shape at a boundary with the first memory region peripheral portion;

on the substrate in the memory region and the first memory region peripheral portion, the first impurity layer and a first insulating layer; and

a first metal wiring layer to be connected to the first gate conductor layer and a second metal wiring layer to be connected to the second gate conductor layer in the first memory region peripheral portion, in which

in the memory region and the first memory region peripheral portion and on the peripheral material layer, from a bottom, the first gate conductor layer, a second insulating layer, the second gate conductor layer, and a third insulating layer are formed such that the first gate conductor layer, the second insulating layer, the second gate conductor layer, and the third insulating layer have a shape that is substantially same as the step-like shape between the first memory region peripheral portion and the peripheral material layer and that at least an upper surface of the third insulating layer in the memory region is positioned lower than the upper surface of the peripheral material layer, and

in the first memory region peripheral portion, the first gate conductor layer and the second gate conductor layer bend upward in a vertical direction along the step-like shape, the first gate conductor layer and the second gate conductor layer have upper surfaces at a same position, and the upper surfaces of the first gate conductor layer and the second gate conductor layer are positioned close to the upper surface of the peripheral material layer (ninth invention).

In the ninth invention, the semiconductor memory device further includes: a fourth insulating layer that is connected to the second insulating layer and the third insulating layer in the first memory region peripheral portion and that extends from an upper surface of the first insulating layer in the vertical direction such that an upper surface of the fourth insulating layer is positioned close to the upper surface of the peripheral material layer (tenth invention).

In the ninth invention, a second memory region peripheral portion opposite to the first memory region peripheral portion with the memory region therebetween in plan view does not have the second insulating layer that bends from a horizontal direction to the vertical direction (eleventh invention).

In the ninth invention, if one of the first impurity layer and the second impurity layer is connected to a source line, another of the first impurity layer and the second impurity layer is connected to a bit line, and

if one of the first gate conductor layer and the second gate conductor layer is connected to a plate line, another of the first gate conductor layer and the second gate conductor layer is connected to a word line (twelfth invention).

In the twelfth invention, the first gate conductor layer is connected to laterally and longitudinally adjacent semiconductor pillars in plan view (thirteenth invention).

In the ninth invention, at least one of the first gate conductor layer and the second gate conductor layer is divided into a plurality of parts in plan view (fourteenth invention).

In the ninth invention, at least one of the first gate conductor layer and the second gate conductor layer is divided into a plurality of parts in a direction perpendicular to the substrate (fifteenth invention).

### BRIEF DESCRIPTION OF THE DRAWINGS

FIG. 1 is a structure diagram of a semiconductor memory device according to a first embodiment.

FIGS. 2A, 2B and 2C are diagrams for describing an erase operation mechanism of the semiconductor memory device according to the first embodiment.

FIGS. 3A, 3B and 3C are diagrams for describing a write operation mechanism of the semiconductor memory device according to the first embodiment.

FIGS. 4AA, 4AB and 4AC are diagrams for describing a read operation mechanism of the semiconductor memory device according to the first embodiment.

FIGS. 4BA, 4BB, 4BC and 4BD are diagrams for describing the read operation mechanism of the semiconductor memory device according to the first embodiment.

FIGS. 5AA, 5AB, 5AC and 5AD are structure diagrams for describing a manufacturing method of the semiconductor memory device according to the first embodiment.

FIGS. 5BA, 5BB, 5BC and 5BD are diagrams for describing the manufacturing method of the semiconductor memory device according to the first embodiment.

FIGS. 5CA, 5CB, 5CC and 5CD are diagrams for describing the manufacturing method of the semiconductor memory device according to the first embodiment.

FIGS. 5DA, 5DB, 5DC and 5DD are diagrams for describing the manufacturing method of the semiconductor memory device according to the first embodiment.

FIGS. 5EA, 5EB, 5EC and 5ED are diagrams for describing the manufacturing method of the semiconductor memory device according to the first embodiment.

FIGS. 5FA, 5FB, 5FC and 5FD are diagrams for describing the manufacturing method of the semiconductor memory device according to the first embodiment.

FIGS. 5GA, 5GB, 5GC and 5GD are diagrams for describing the manufacturing method of the semiconductor memory device according to the first embodiment.

FIGS. 5HA, 5HB, 5HC and 5HD are diagrams for describing the manufacturing method of the semiconductor memory device according to the first embodiment.

FIGS. 5IA, 5IB, 5IC and 5ID are diagrams for describing the manufacturing method of the semiconductor memory device according to the first embodiment.

FIGS. 5JA, 5JB, 5JC and 5JD are diagrams for describing the manufacturing method of the semiconductor memory device according to the first embodiment.

FIGS. 5KA 5KB, 5KC and 5KD are diagrams for describing the manufacturing method of the semiconductor memory device according to the first embodiment.

FIGS. 6AA, 6AB, 6AC and 6AD are diagrams for describing a manufacturing method of a semiconductor memory device according to a second embodiment.

FIGS. 6BA 6BB, 6BC and 6BD are diagrams for describing the manufacturing method of the semiconductor memory device according to the second embodiment.

FIGS. 6CA, 6CB, 6CC and 6CD are diagrams for describing the manufacturing method of the semiconductor memory device according to the second embodiment.

FIGS. 7AA, 7AB, 7AC and 7AD are diagrams for describing a manufacturing method of a semiconductor memory device according to a third embodiment.

FIGS. 7BA, 7BB, 7BC and 7BD are diagrams for describing the manufacturing method of the semiconductor memory device according to the third embodiment.

FIGS. 8A, 8B, 8C and 8D are diagrams for describing a write operation of a DRAM memory cell including no capacitor in the related art.

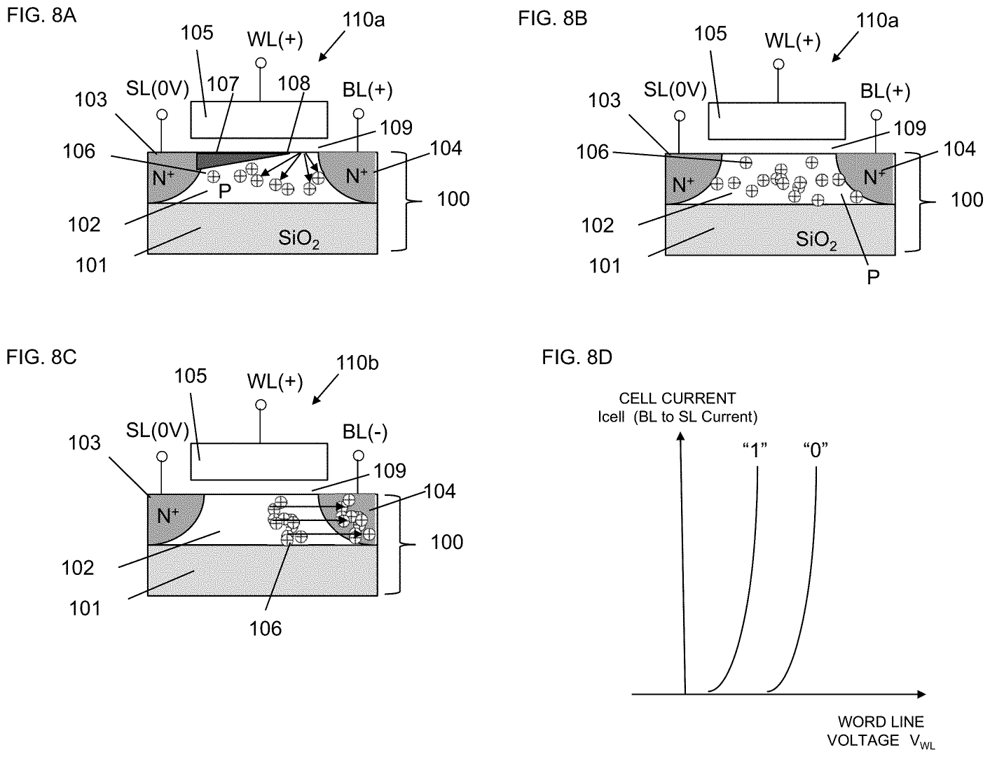

FIGS. 9A and 9B are diagrams for describing a problem of the operation of the DRAM memory cell including no capacitor in the related art.

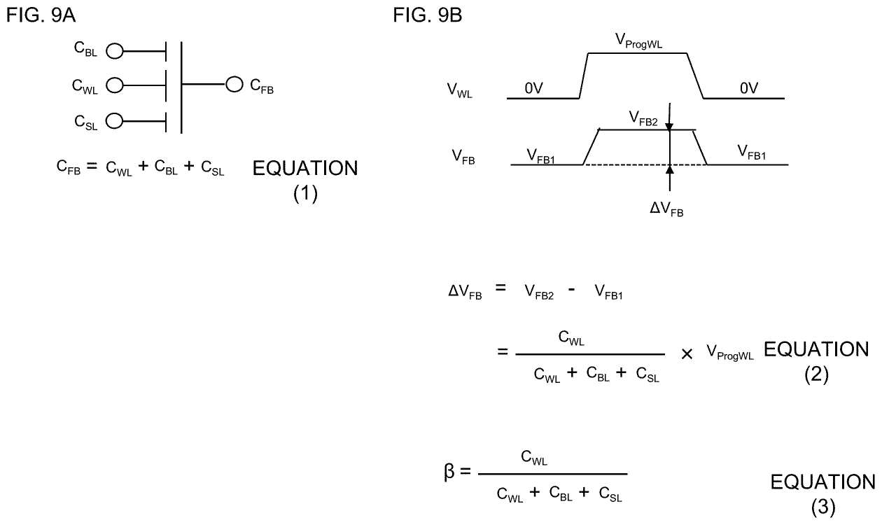

FIGS. 10A, 10B and 10C are diagrams for describing a read operation of the DRAM memory cell including no capacitor in the related art.

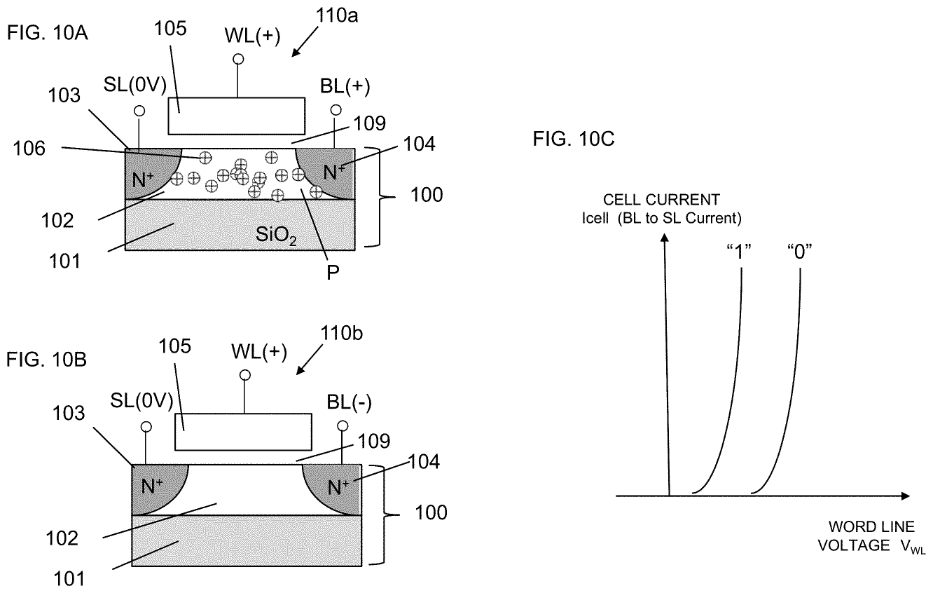

### DESCRIPTION OF THE PREFERRED EMBODIMENTS

Hereinafter, structures, operation mechanisms, and manufacturing methods of a semiconductor memory device (hereinafter referred to as dynamic flash memory) according to embodiments of the present invention will be described with reference to the drawings.

### First Embodiment

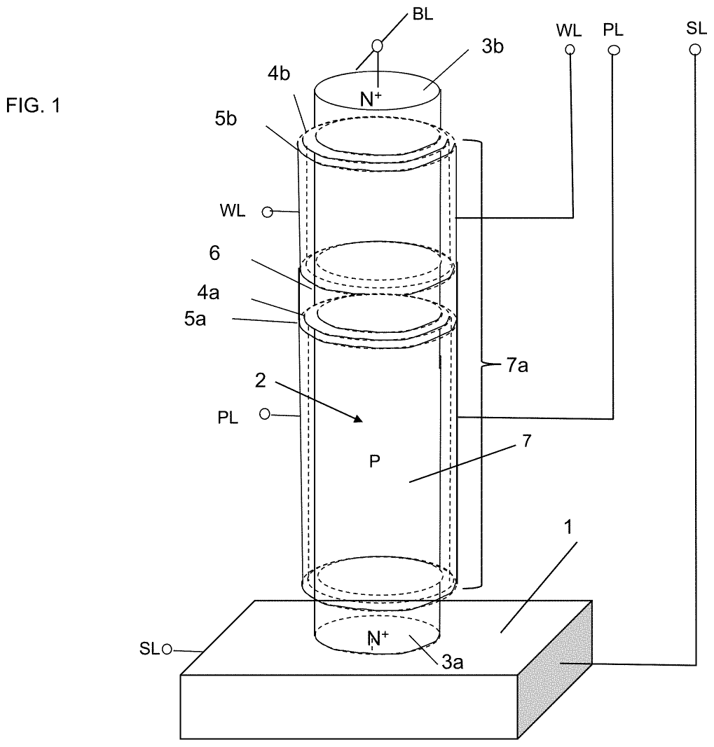

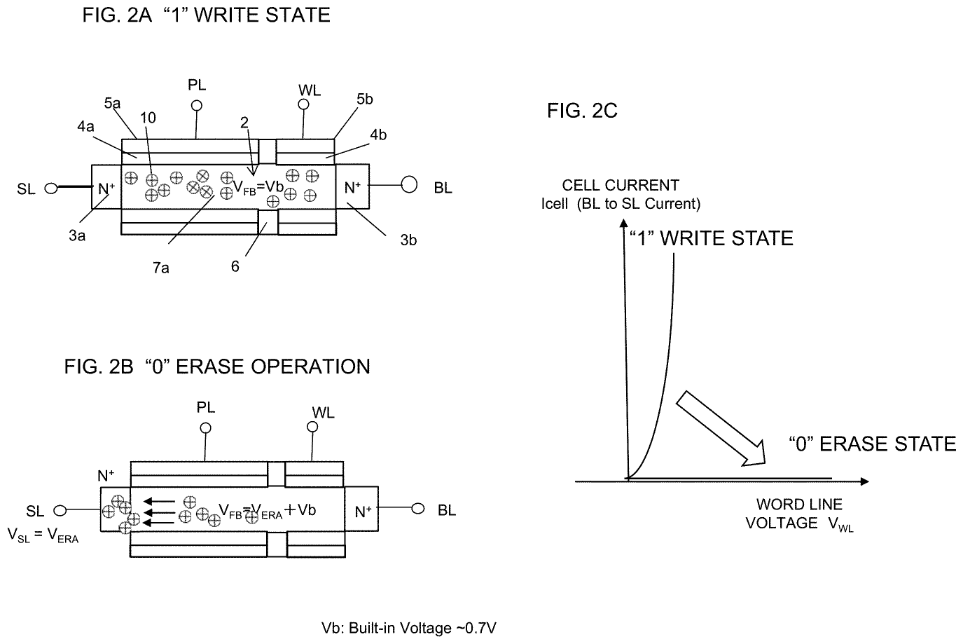

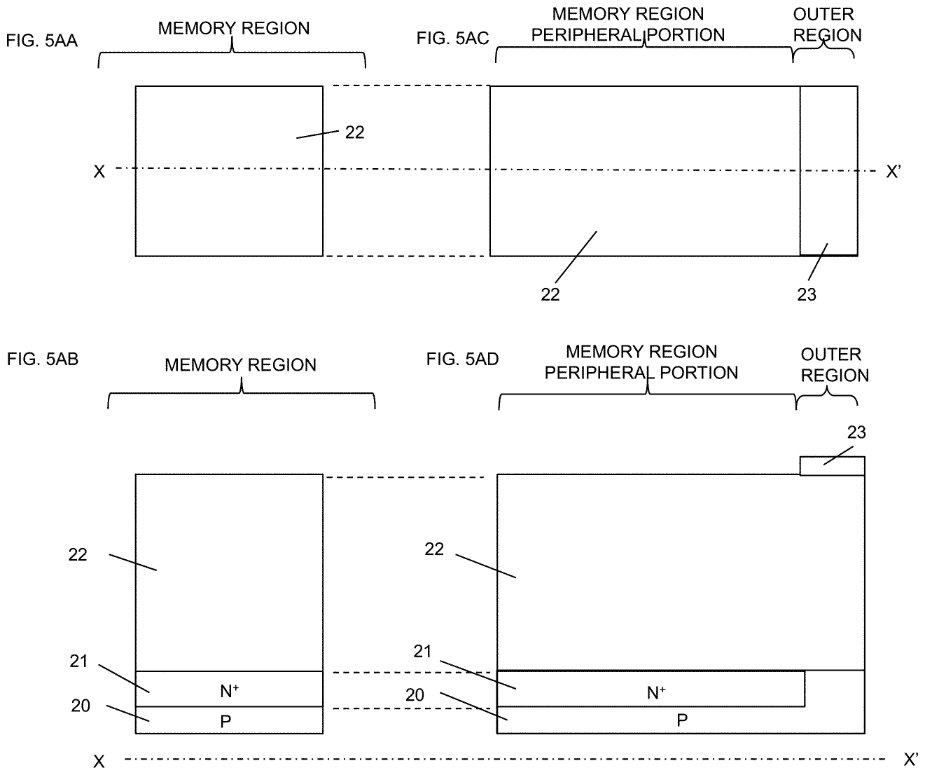

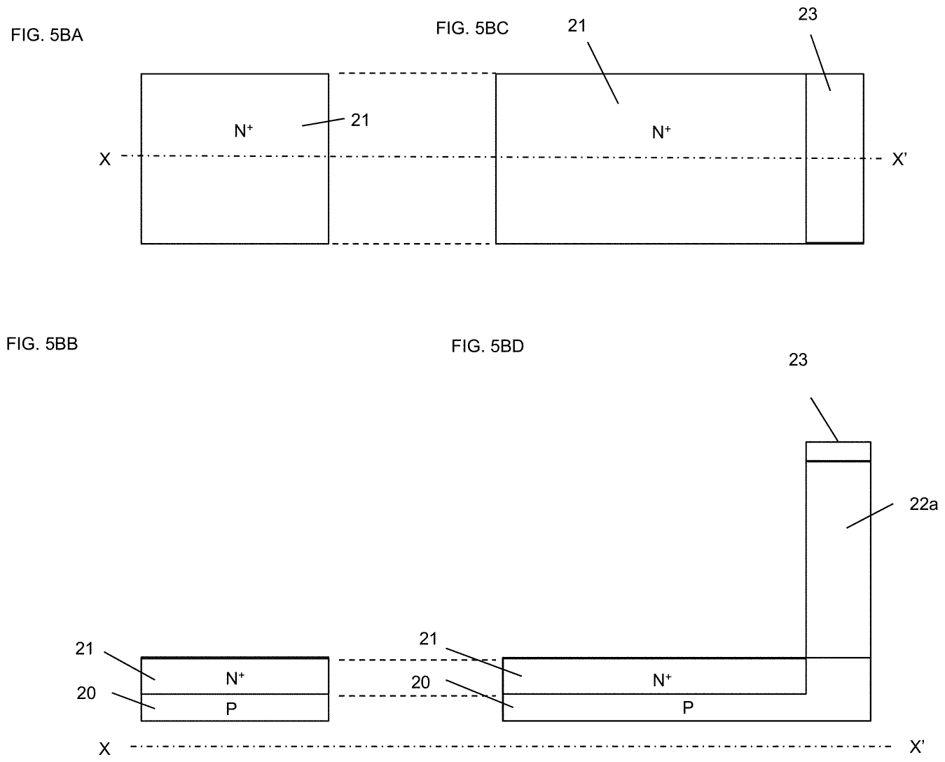

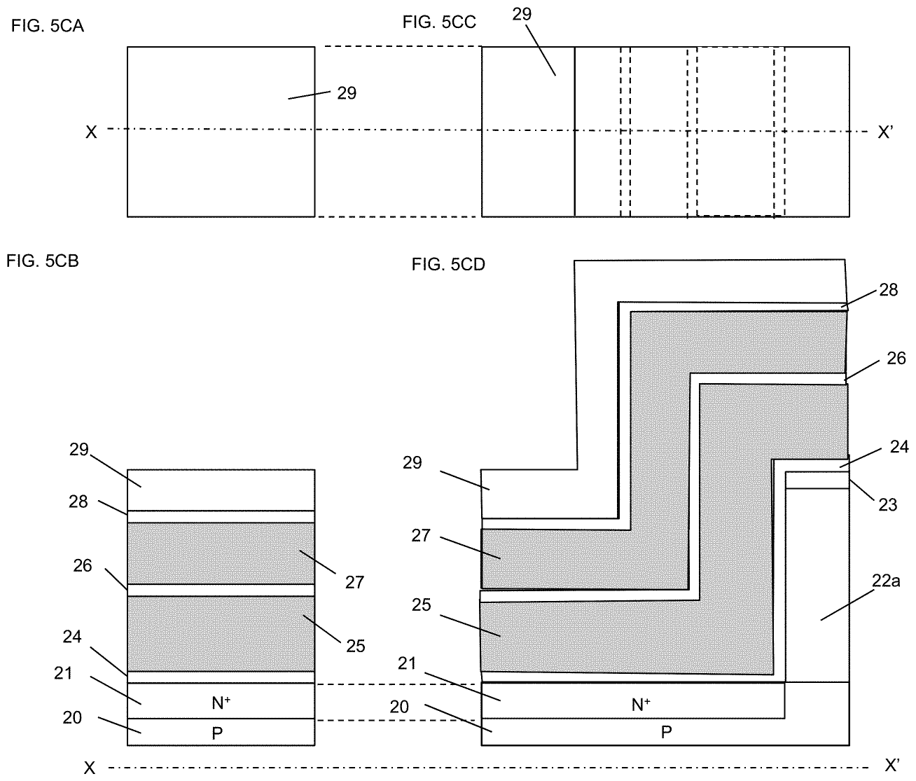

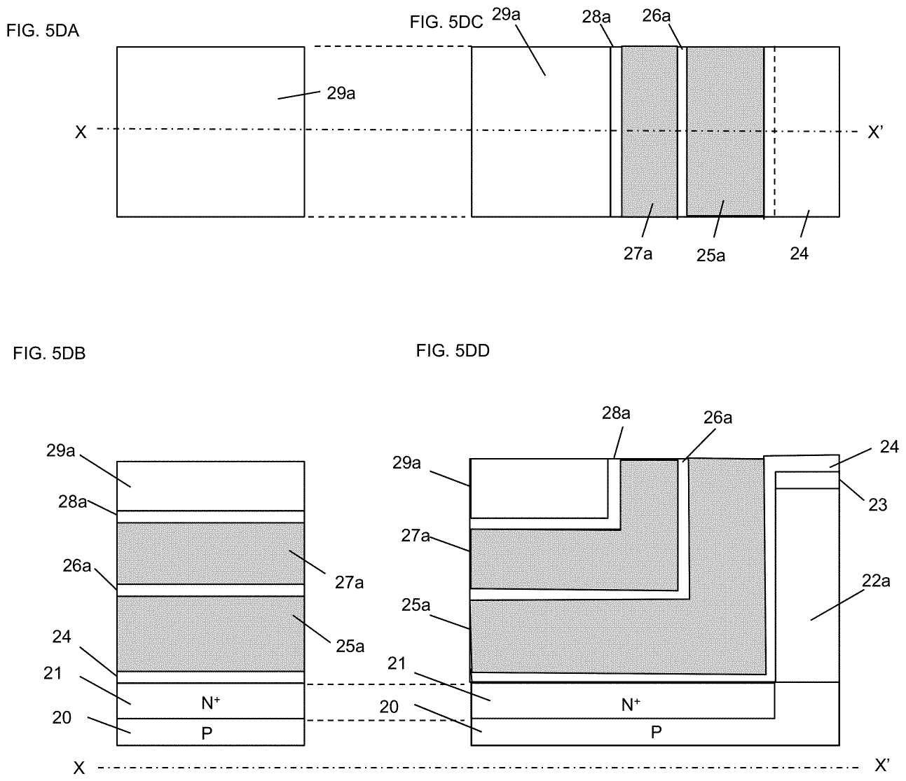

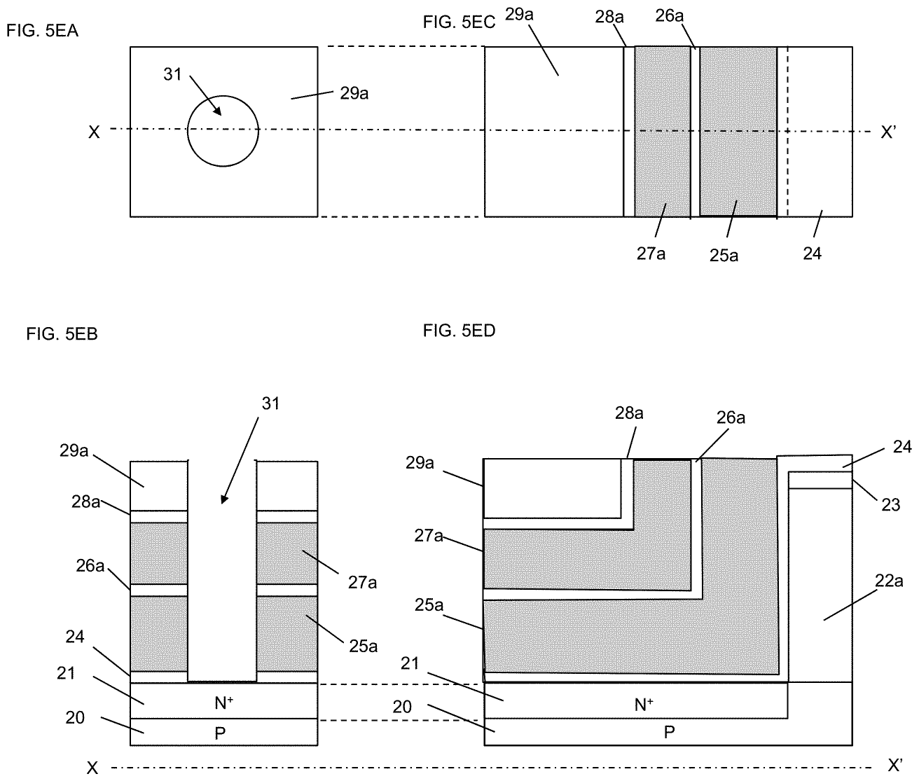

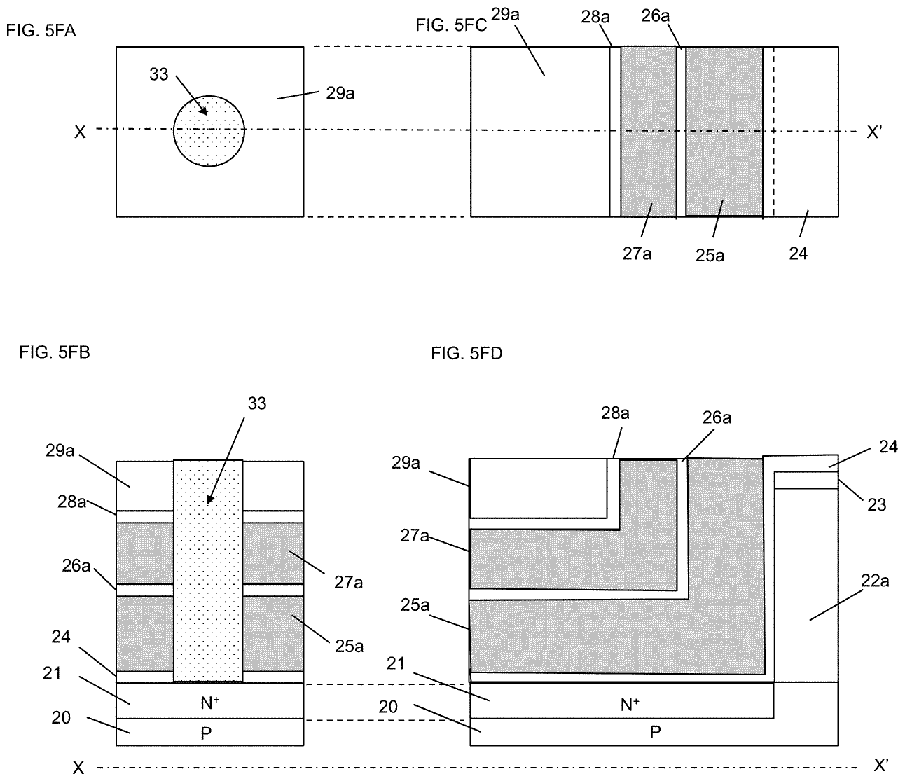

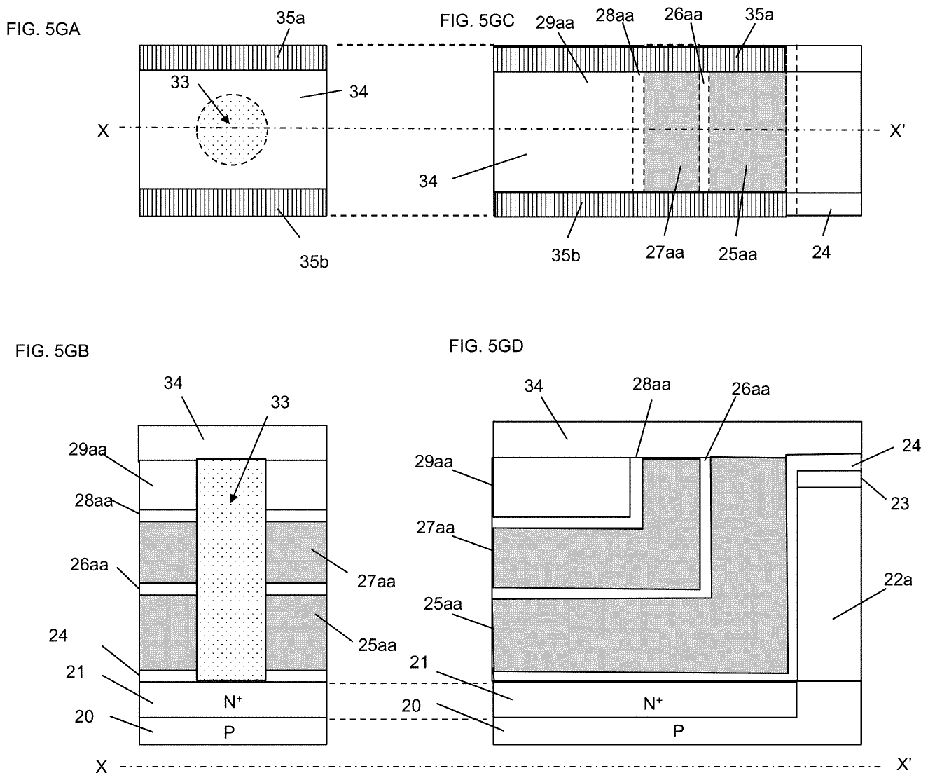

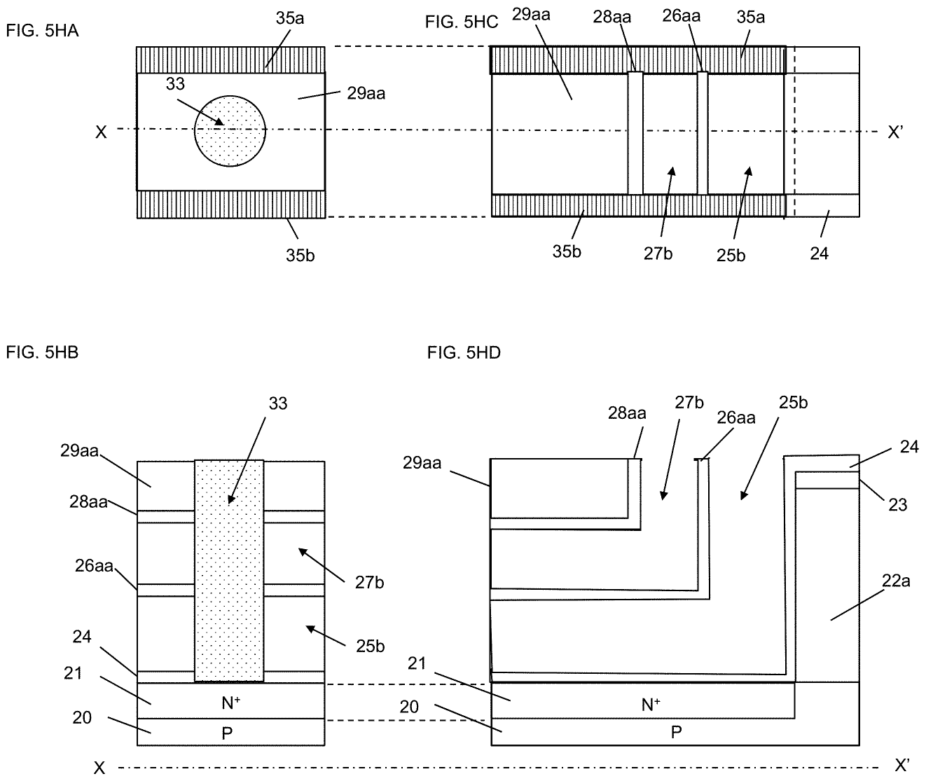

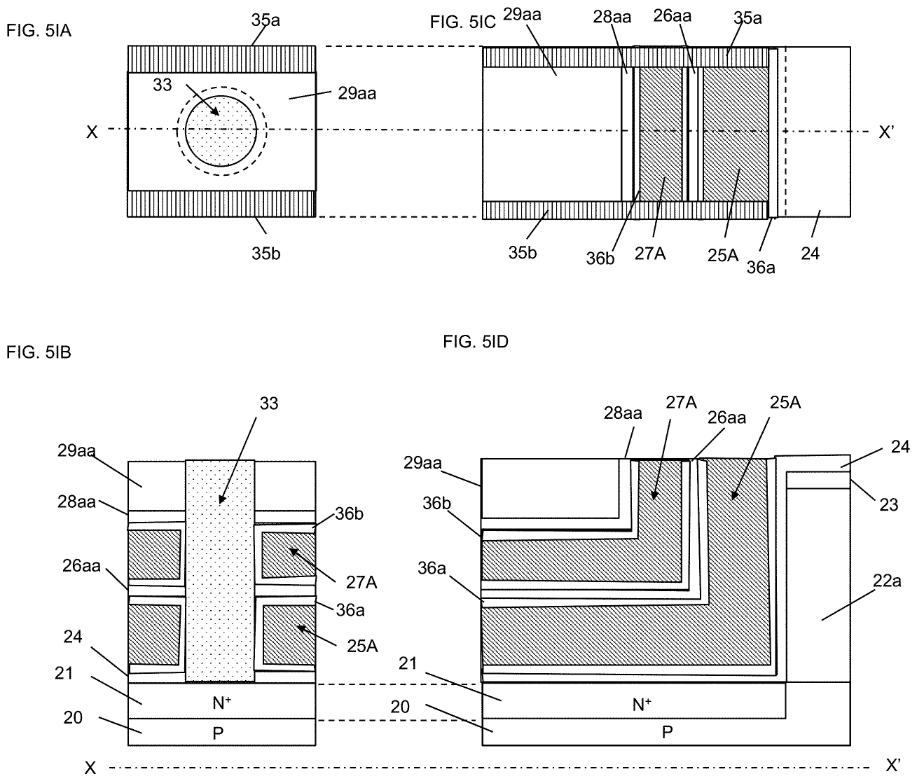

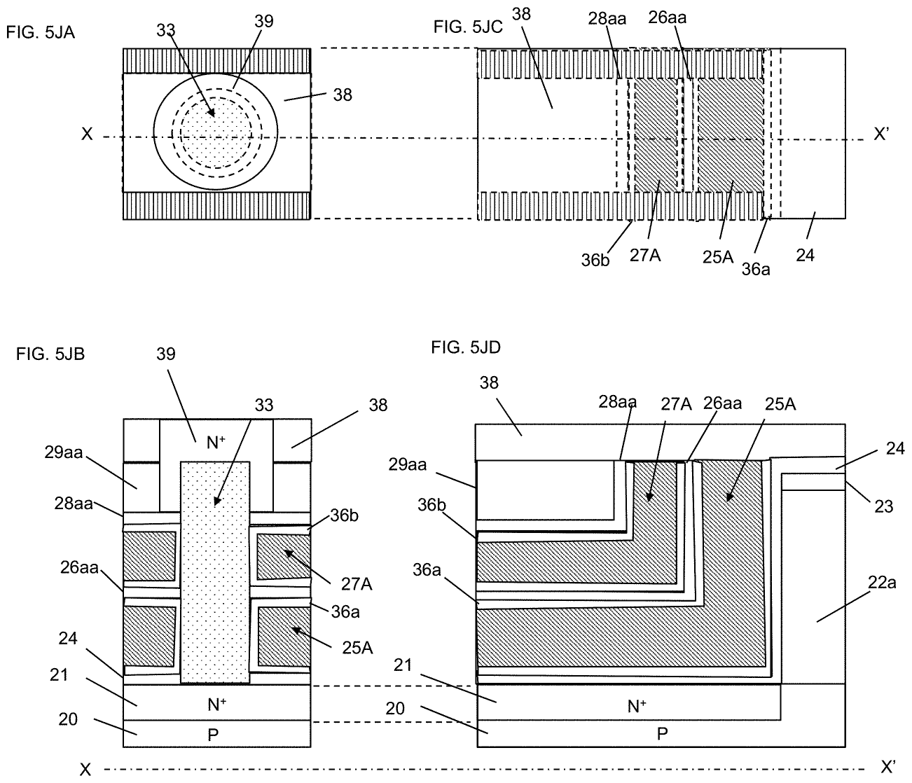

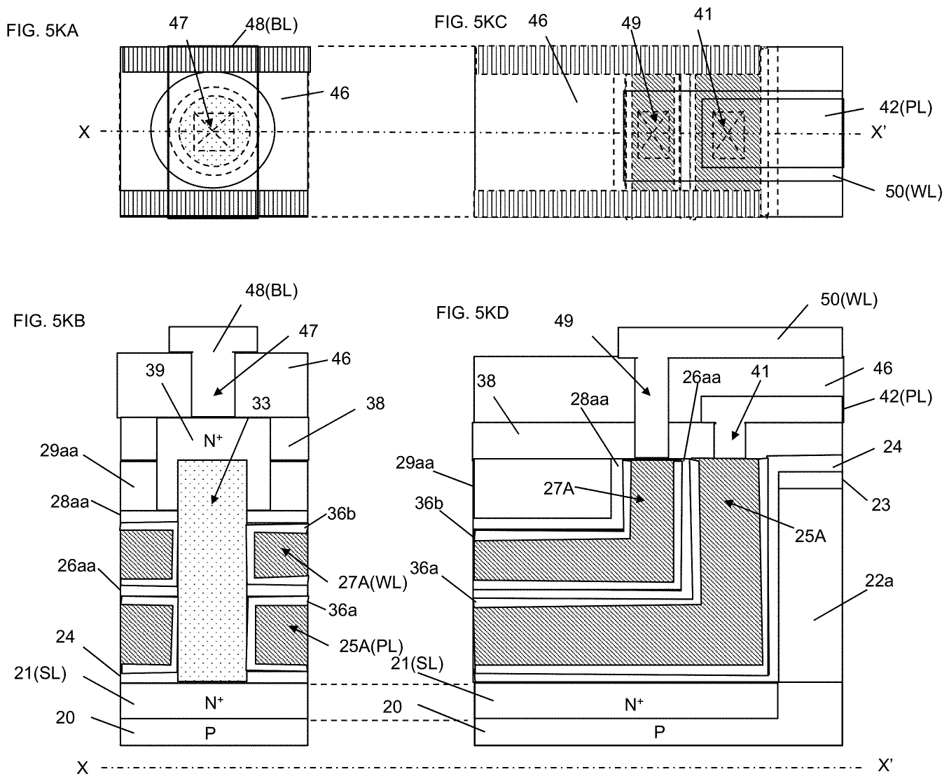

A structure, operation mechanisms, and a manufacturing method of a dynamic flash memory cell according to a first embodiment of the present invention will be described with reference to FIGS. 1 to 5KC. The structure of the dynamic flash memory cell will be described with reference to FIG. 1. In addition, a data erase mechanism, a data write mechanism, and a data read mechanism will be described with reference to FIGS. 2A to 2C, FIGS. 3A to 3C, and FIGS. 4AA to 4BD, respectively. Furthermore, the manufacturing method of the dynamic flash memory will be described with reference to FIGS. 5AA to 5KC.

FIG. 1 illustrates the structure of the dynamic flash memory cell according to the first embodiment of the present invention. On a substrate 1 (which is an example of “substrate” in the claims), there is a silicon semiconductor pillar 2 (which is an example of “semiconductor pillar” in the claims) (hereinafter the silicon semiconductor pillar will be referred to as “Si pillar”). In the Si pillar 2, from the bottom, there are an N⁺ layer 3a (which is an example of “first impurity layer” in the claims), a semiconductor region 7 containing an acceptor impurity (hereinafter, a semiconductor region containing an acceptor impurity will be referred to as “P layer”), and an N⁺ layer 3b (which is an example of “second impurity layer” in the claims). The P layer 7 between the N layers 3a and 3b serves a channel region 7a. There are a first gate insulating layer 4a (which is an example of “first gate insulating layer” in the claims) surrounding a lower portion of the Si pillar 2 and a second gate insulating layer 4b (which is an example of “second gate insulating layer” in the claims) surrounding an upper portion of the Si pillar 2. In addition, there are a first gate conductor layer 5a (which is an example of “first gate conductor layer” in the claims) surrounding the first gate insulating layer 4a and a second gate conductor layer 5b (which is an example of “second gate conductor layer” in the claims) surrounding the second gate insulating layer 4b. Furthermore, the first gate conductor layer 5a and the second gate conductor layer 5b are isolated from each other by an insulating layer 6. Thus, the N⁺ layers 3a and 3b, the P layer 7, the first gate insulating layer 4a, the second gate insulating layer 4b, the first gate conductor layer 5a, and the second gate conductor layer 5b constitute the dynamic flash memory cell.

As illustrated in FIG. 1, the N⁺ layer 3a, the N⁺ layer 3b, the first gate conductor layer 5a, and the second gate conductor layer 5b are respectively connected to a source line SL (which is an example of “source line” in the claims), a bit line BL (which is an example of “bit line” in the claims), a plate line PL (which is an example of “plate line” in the claims), and a word line WL (which is an example of “word line” in the claims). The source line SL, the plate line PL, the word line WL, and the bit line BL are continuous between adjacent memory cells and are connected to wiring conductor layers that are present in an upper portion in the direction perpendicular to the substrate 1 from the periphery of the memory region.

Note that a gate capacitance of the first gate conductor layer 5a connected to the plate line PL is desirably configured to be greater than a gate capacitance of the second gate conductor layer 5b connected to the word line WL.

The first gate conductor layer 5a may be divided into two or more parts, and the divided two or more parts may be operated synchronously or asynchronously as conductive electrodes of the plate line PL. Similarly, the second gate conductor layer 5b may be divided into two or more parts, and the divided two or more parts may be operated synchronously or asynchronously as conductive electrodes of the word line WL. In these manners, dynamic flash memory operations may also be performed.

An erase operation mechanism will be described with reference to FIGS. 2A to 2C. The channel region 7a between the N⁺ layers 3a and 3b is electrically isolated from the substrate 1 and serves as a floating body. FIG. 2A illustrates a state in which a group of holes 10 generated by impact ionization in a previous cycle are stored in the channel region 7a before an erase operation. Then, as illustrated in FIG. 2B, at the time of the erase operation, the voltage of the source line SL is set to a negative voltage V_{ERA}. Here, V_{ERA} is −3 V, for example. Accordingly, regardless of the value of the initial potential of the channel region 7a, the PN junction between the channel region 7a and the N⁺ layer 3a serving as a source and connected to the source line SL becomes forward biased. As a result, the group of holes 10 stored in the channel region 7a, generated by impact ionization in the previous cycle, are sucked into the N⁺ layer 3a of the source portion, and a potential V_{FB} of the channel region 7a becomes V_{FB}=V_{ERA}+Vb. Here, Vb is the built-in voltage of the PN junction and is about 0.7 V. Therefore, if V_{ERA}=−3 V, the potential of the channel region 7a is −2.3 V. This value corresponds to the potential state of the channel region 7a in the erase state. Therefore, if the potential of the channel region 7a of the floating body becomes a negative voltage, the threshold voltage of the N-channel MOS transistor of the dynamic flash memory cell is increased due to a substrate biasing effect. This results in a higher threshold voltage for the second gate conductor layer 5b connected to this word line WL, as illustrated in FIG. 2C. The erase state of this channel region 7a is logic storage data “0”. Note that the above-described conditions of voltages applied to the bit line BL, the source line SL, the word line WL, and the plate line PL and the potential of the floating body are examples for performing the erase operation, and any other operation conditions may be employed by which the erase operation can be performed.

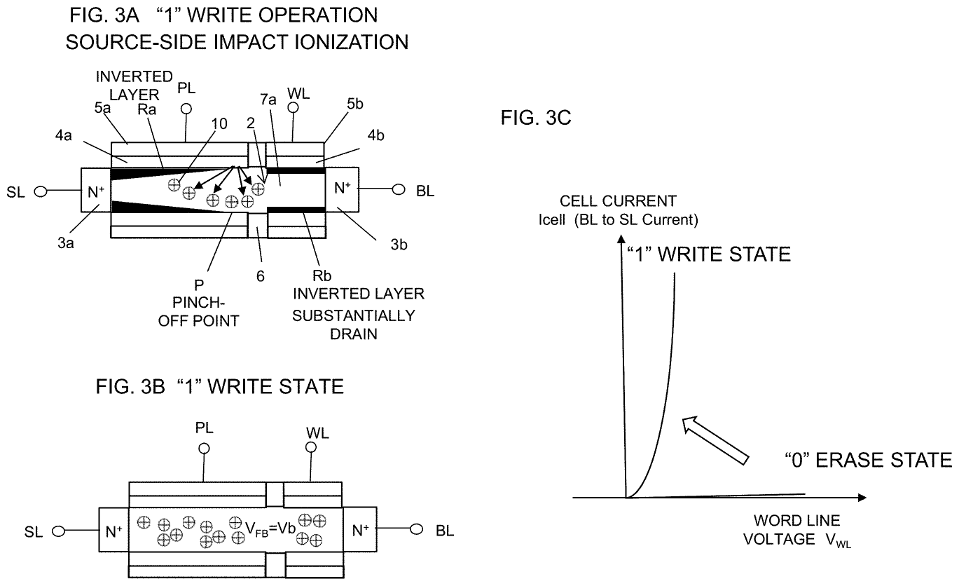

FIGS. 3A to 3C illustrate a write operation of the dynamic flash memory cell. In FIG. 3A, for example, 0 V is input to the N⁺ layer 3a connected to the source line SL, 3 V is input to the N⁺ layer 3b connected to the bit line BL, 2 V is input to the first gate conductor layer 5a connected to the plate line PL, and, 5 V is input to the second gate conductor layer 5b connected to the word line WL. As a result, as illustrated in FIG. 3A, a ring-shaped inverted layer Ra is formed in the channel region 7a inside the first gate conductor layer 5a connected to the plate line PL, and a first N-channel MOS transistor region including the first gate conductor layer 5a is operated in the saturation region. Accordingly, there is a pinch-off point P in the inverted layer Ra inside the first gate conductor layer 5a connected to the plate line PL. On the other hand, a second N-channel MOS transistor region including the second gate conductor layer 5b connected to the word line WL is operated in the linear region. Accordingly, the channel region 7a inside the second gate conductor layer 5b connected to the word line WL does not include a pinch-off point, and an inverted layer Rb is entirely formed.

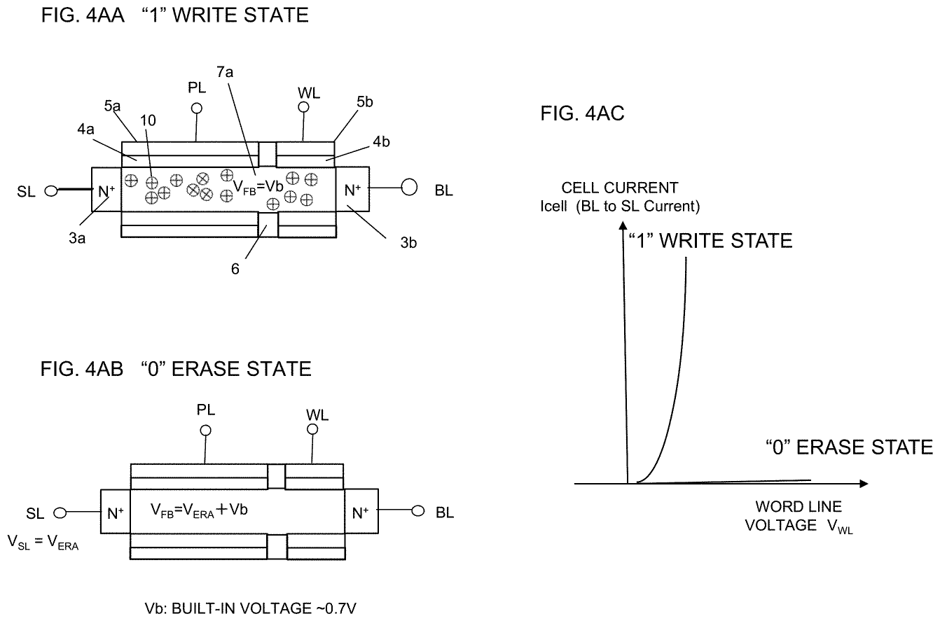

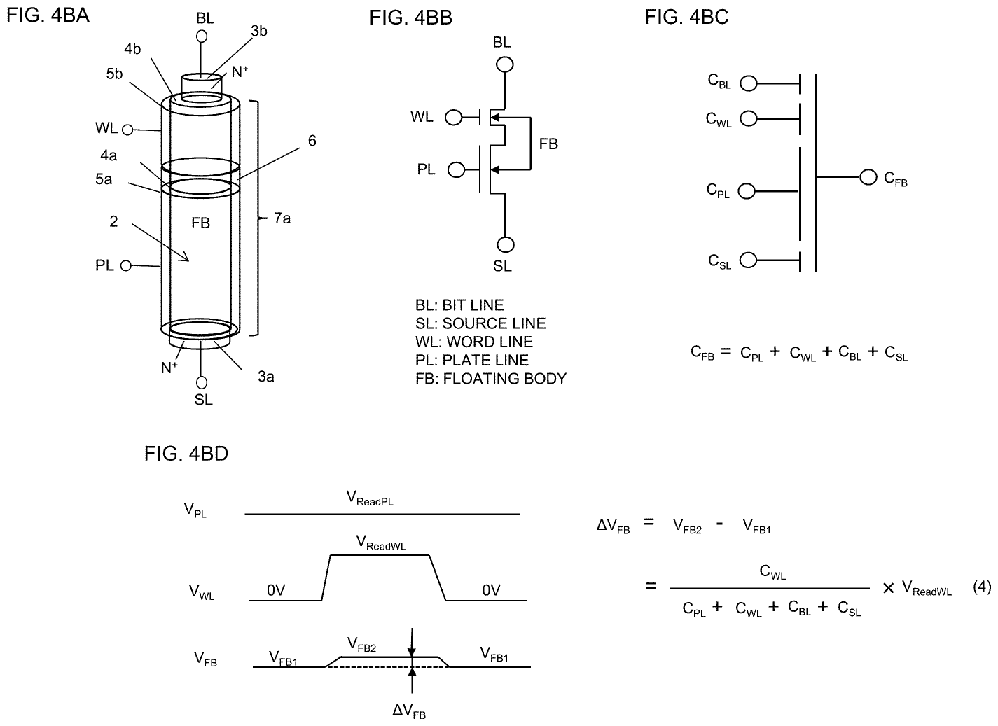

The inverted layer Rb formed entirely inside the second gate conductor layer 5b connected to the word line WL substantially serves as a drain of the first N-channel MOS transistor region including the first gate conductor layer 5a. As a result, the electric field strength becomes maximum in a first boundary region of the channel region 7a between the first N-channel MOS transistor region, including the first gate conductor layer 5a, and the second N-channel MOS transistor region, including the second gate conductor layer 5b, which are connected in series, and an impact ionization phenomenon occurs in this region. This region is a region on the source side when viewed from the second N-channel MOS transistor region including the second gate conductor layer 5b connected to the word line WL, and thus, this phenomenon is referred to as a source-side impact ionization phenomenon. As a result of this source-side impact ionization phenomenon, electrons flow from the N⁺ layer 3a connected to the source line SL toward the N⁺ layer 3b connected to the bit line BL. The accelerated electrons collide with lattice Si atoms, and electron-hole pairs are generated by the kinetic energy. Although some of the generated electrons flow into the first gate conductor layer 5a and the second gate conductor layer 5b, most of the generated electrons flow into the N⁺ layer 3b connected to the bit line BL. At the time of writing “1”, electron-hole pairs may be generated by a gate induced drain leakage (GIDL) current, and the floating body (denoted by “FB” in FIG. 4BB) may be charged with the generated group of holes (see, for example, E. Yoshida, and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-697, April 2006).

As illustrated in FIG. 3B, the generated group of holes 10 serve as majority carriers in the channel region 7a and charge the channel region 7a to a positive bias. Since the N⁺ layer 3a connected to the source line SL is at 0 V, the channel region 7a is charged up to the built-in voltage Vb (about 0.7 V) of the PN junction between the channel region 7a and the N⁺ layer 3a connected to the source line SL. If the channel region 7a is charged to a positive bias, the threshold voltages of the first N-channel MOS transistor region and the second N-channel MOS transistor region decrease due to the substrate bias effect. Accordingly, as illustrated in FIG. 3C, the threshold voltage of the second N-channel MOS transistor region connected to the word line WL decreases. This write state of the channel region 7a is assigned to logical storage data “1”.

At the time of the write operation, instead of the first boundary region, in a second boundary region between the N⁺ layer 3a and the channel region 7a or a third boundary region between the N⁺ layer 3b and the channel region 7a, electron-hole pairs may be generated by the impact ionization phenomenon or the GIDL current, and the generated group of holes 10 may charge the channel region 7a. Note that the above-described conditions of voltages applied to the bit line BL, the source line SL, the word line WL, and the plate line PL are examples for performing the write operation, and any other voltage conditions may be employed by which the write operation can be performed.

A read operation of the dynamic flash memory cell will be described with reference to FIGS. 4AA to 4BD. With reference to FIGS. 4AA to 4AC, the read operation of the dynamic flash memory cell will be described. As illustrated in FIG. 4AA, if the channel region 7a is charged up to the built-in voltage Vb (about 0.7 V), the threshold voltage decreases due to the substrate bias effect. This state is assigned to logical storage data “1”. As illustrated in FIG. 4AB, if a memory block selected before writing is in an erase state “0” in advance, the floating voltage V_{FB} of the channel region 7a is V_{ERA}+Vb. A write state “1” is stored at random by the write operation. As a result, logical storage data of logical “0” and “1” is created for the word line WL. As illustrated in FIG. 4AC, the level difference between the two threshold voltages for the word line WL is utilized to perform reading by a sense amplifier.

With reference to FIGS. 4BA to 4BD, a relationship among the gate capacitances of the first gate conductor layer 5a and the second gate conductor layer 5b at the time of the read operation of the dynamic flash memory cell and an operation related thereto will be described. The gate capacitance of the second gate conductor layer 5b connected to the word line WL is desirably designed to be smaller than the gate capacitance of the first gate conductor layer 5a connected to the plate line PL. As illustrated in FIG. 4BA, a vertical-direction length of the first gate conductor layer Sa connected to the plate line PL is set to be longer than a vertical-direction length of the second gate conductor layer 5b connected to the word line WL so as to make the gate capacitance of the second gate conductor layer 5b connected to the word line WL smaller than the gate capacitance of the first gate conductor layer 5a connected to the plate line PL. FIG. 4BB illustrates an equivalent circuit of the single dynamic flash memory cell in FIG. 4BA.

FIG. 4BC illustrates a relationship among coupling capacitances in the dynamic flash memory. Here, C_{WL} denotes a capacitance of the second gate conductor layer 5b, C_{PL} denotes a capacitance of the first gate conductor layer Sa, C_{BL} denotes a capacitance of the PN junction between the channel region 7a and the N⁺ layer 3b serving as the drain, and C_{SL} denotes a capacitance of the PN junction between the channel region 7a and the N⁺ layer 3a serving as the source. As illustrated in FIG. 4BD, if the voltage of the word line WL swings, the change affects the channel region 7a as noise. A potential change ΔV_{FB} of the channel region 7a at this time is expressed as follows.

ΔV_{FB}=C_{WL}/(C_{PL}+C_{WL}+C_{BL}+C_{SL})×V_{ReadWL} (4)

Here, V_{ReadWL} denotes the potential at the word line WL changed at the time of reading. As is apparent from Equation (4), if the contribution ratio of C_{WL} is made smaller than that of the total capacitance C_{PL}+C_{WL}+C_{BL}+C_{SL} of the channel region 7a, ΔV_{FB} is decreased. If the vertical-direction length of the first gate conductor layer 5a connected to the plate line PL is made even longer than the vertical-direction length of the second gate conductor layer 5b connected to the word line WL, ΔV_{FB} may be further decreased without reducing the degree of integration of the memory cell in plan view. Note that the above-described conditions of voltages applied to the bit line BL, the source line SL, the word line WL, and the plate line PL and the potential of the floating body are examples for performing the read operation, and any other operation conditions may be employed by which the read operation can be performed.

The manufacturing method of the semiconductor memory device according to the first embodiment will be described with reference to FIGS. 5AA to 5KD. In the semiconductor memory device, in plan view, there are a memory region (which is an example of “memory region” in the claims) in which memory cells are arranged two-dimensionally, a memory region peripheral portion (which is an example of “first memory region peripheral portion” in the claims) connected to an outer side of the memory region, and an outer region (which is an example of “outer region” in the claims) connected to the memory region peripheral portion. Among FIGS. 5AA to 5KD, FIGS. 5AA, 5BA, 5CA, 5DA, 5EA, 5FA, 5GA, 5HA, 5IA, 5JA, and 5KA are plan views of a single memory cell in the memory region of the semiconductor memory device, and FIGS. 5AC, 5BC, 5CC, 5DC, 5EC, 5FC, 5GC, 5HC, 5IC, 5JC, and 5KC are plan views of the memory region peripheral portion and the outer region. FIGS. 5AB, 5BB, 5CB, 5DB, 5EB, 5FB, 5GB, 5HB, 5IB, 5JB, and 5KB are sectional views of the single memory cell, and FIGS. 5AD, 5BD, 5CD, 5DD, 5ED, 5FD, 5GD, 5HD, 5ID, 5JD, and 5KD are sectional views of the memory region peripheral portion and the outer region, taken along line X-X′ in FIGS. 5AA and 5AC, 5BA and 5BC, 5CA and 5CC, 5DA and 5DC, 5EA and 5EC, 5FA and 5FC, 5GA and 5GC, 5HA and 5HC, 5IA and 5IC, 5JA and 5JC, and 5KA and 5KC, respectively.

As illustrated in 5AA to 5AD, on a P-layer substrate 20 (which is an example of “substrate” in the claims), the following layers are formed from the bottom: an N⁺ layer 21 (which is an example of “first impurity layer” in the claims), a SiO₂ layer 22, and a mask insulating layer 23. The mask insulating layer 23 is in the outer region that is on an outer side of the memory region peripheral portion. The N⁺ layer 21 is formed to be continuous from the memory region to the memory region peripheral portion. Note that the N⁺ layer 21 is formed by, for example, photolithography, reactive ion etching (RIE), epitaxial crystal growth, chemical mechanical polishing (CMP), or the like before the SiO₂ layer 22 is formed.

Subsequently, as illustrated in FIGS. 5BA to 5BD, by using the mask insulating layer 23 as a mask, the SiO₂ layer 22 is etched to form a SiO₂ layer 22a (which is an example of “peripheral material layer” in the claims) in the outer region. The upper surface of the SiO₂ layer 22a is at a position higher than the upper surface of the N layer 21 in the memory region and the memory region peripheral portion, and the boundary between the memory region peripheral portion and the outer region has a step-like shape.

Subsequently, as illustrated in FIGS. 5CA to 5CD, the following layers are deposited from the bottom by, for example, chemical vapor deposition (CVD): a first insulating layer 24 (which is an example of “first insulating layer” in the claims), a first material layer 25 (which is an example of “first material layer” in the claims), a second insulating layer 26 (which is an example of “second insulating layer” in the claims), a second material layer 27 (which is an example of “second material layer” in the claims), a third insulating layer 28 (which is an example of “third insulating layer” in the claims), a third material layer 29 to be continuous from the memory region and the memory region peripheral portion to an upper portion of the SiO₂ layer 22a in the outer region. At this time, in the boundary between the memory region peripheral portion and the outer region, each of the first insulating layer 24, the first material layer 25, the second insulating layer 26, the second material layer 27, the third insulating layer 28, and the third material layer 29 bends upward along the step-like shape of the boundary and has substantially the same step-like shape. Note that the third material layer 29 may also be formed by depositing a thick third insulating layer 28. In addition, the third material layer 29 in the memory region and the memory region peripheral portion may also be formed by CVD and CMP to be substantially flush with the third insulating layer 28 in the outer region. Furthermore, the first insulating layer 24 may also be formed separately in the memory region and the memory region peripheral portion.

Subsequently, as illustrated in FIGS. 5DA to 5DD, the first material layer 25, the second insulating layer 26, the second material layer 27, the third insulating layer 28, and the third material layer 29 are polished by CMP to be flush with the first insulating layer 24 in the outer region. Thus, a first material layer 25a, a second insulating layer 26a, a second material layer 27a, a third insulating layer 28a, and a third material layer 29a are formed.

Subsequently, as illustrated in FIGS. 5EA to 5ED, in the memory region, the first insulating layer 24, the first material layer 25a, the second insulating layer 26a, the second material layer 27a, the third insulating layer 28a, and the third material layer 29a are etched to form a hole 31 (which is an example of “first hole” in the claims).

Subsequently, as illustrated in FIGS. 5FA to 5FD, a Si pillar 33 (which is an example of “semiconductor pillar” in the claims) embedded in the hole 31 is formed by epitaxial crystal growth, metal-assisted solid-phase crystallization (MSC), metal induced lateral crystallization (MILC), or the like.

Subsequently, as illustrated in FIGS. 5GA to 5GD, a mask material layer 34 is formed. In plan view, the mask material layer 34 covers the Si pillar 33 and extends in the line X-X′ direction to reach the memory region peripheral portion and the outer region. Then, by using the mask material layer 34 as an etching mask, the third material layer 29a, the third insulating layer 28a, the second material layer 27a, the second insulating layer 26a, and the first material layer 25a are etched by RIE to form a third material layer 29aa, a third insulating layer 28aa, a second material layer 27aa, a second insulating layer 26aa, and a first material layer 25aa. Then, insulating layers 35a and 35b (which are examples of “fourth insulating layer” in the claims) are formed and embedded in spaces on side surfaces of the third material layer 29aa, the third insulating layer 28aa, the second material layer 27aa, the second insulating layer 26aa, and the first material layer 25aa in the direction perpendicular to the line X-X′.

Subsequently, as illustrated in FIGS. 5HA to 5HD, the first material layer 25aa and the second material layer 27aa are removed by etching to form a hole 25b (which is an example of “second hole” in the claims) and a hole 27b (which is an example of “third hole” in the claims). In this case, in the memory region and the memory region peripheral portion, the insulating layers 35a and 35b serve as supporters for the second insulating layer 26aa, the third insulating layer 28aa, and the third material layer 29aa that are suspended. In addition, in the memory region, the Si pillar 33 also serves as a supporter for the second insulating layer 26aa, the third insulating layer 28aa, and the third material layer 29aa.

Subsequently, for example, HfO₂ layers (not illustrated) to serve as gate insulating layers and TiN layers (not illustrated) to serve as gate conductor layers are formed by atomic layer deposition (ALD) in the holes 25b and 27b and on upper surfaces of the Si pillar 33 and the third material layer 29aa. Then, the HfO₂ layers and the TiN layers are polished by CMP to the positions of the upper surfaces of the Si pillar 33 and the third material layer 29aa, to form HfO₂ layers 36a and 36b (which are examples of “first gate insulating layer” in the claims), a TiN layer 25A (which is an example of “first conductor layer” in the claims), and a TiN layer 27A (which is an example of “second conductor layer” in the claims), as illustrated in FIGS. 5IA to 5ID.

Subsequently, as illustrated in FIGS. 5JA to 5JD, a SiO₂ layer 38 is formed entirely. Then, an N⁺ layer 39 (which is an example of “second impurity layer” in the claims) is formed by epitaxial crystal growth or the like and CMP in a contact hole surrounding a top portion of the Si pillar 33.

Subsequently, as illustrated in FIGS. 5KA to 5KD, a contact hole 41 is formed in the SiO₂ layer 38 on the TiN layer 25A in the memory region peripheral portion. Then, a metal wiring layer 42 (which is an example of “first metal wiring layer” in the claims) connected to the TiN layer 25A via the contact hole 41 is formed. Then, a SiO₂ layer 46 is formed entirely. In addition, a contact hole 47 is formed on the N⁺ layer 39, and a contact hole 49 is formed on the TiN layer 27A. Then, a metal wiring layer 48 connected to the N⁺ layer 39 via the contact hole 47 is formed, and a metal wiring layer 50 (which is an example of “second metal wiring layer” in the claims) connected to the TiN layer 27A via the contact hole 49 is formed. The metal wiring layer 42 is connected to the plate line PL, the metal wiring layer 48 is connected to the bit line BL, and the metal wiring layer 50 is connected to the word line WL. In addition, the N⁺ layer 21 is connected to the source line SL via an embedded metal wiring layer (not illustrated), such as a tungsten (W) layer, from the peripheral portion of the Si pillar 33. Thus, a semiconductor memory device is formed on the P-layer substrate 20.

Note that the Si pillar 33 may also be formed of another semiconductor layer. In addition, Si pillars, each of which is the Si pillar 33, may be arranged on the P-layer substrate 20 in a square lattice, a diagonal lattice, a honeycomb pattern, a zigzag pattern, a serrated pattern, or the like.

The insulating layers 35a and 35b formed on the side surfaces of the third material layer 29aa, the third insulating layer 28aa, the second material layer 27aa, the second insulating layer 26aa, and the first material layer 25aa in the direction perpendicular to the line X-X′ in FIGS. 5GA to 5GD may be formed only in the memory region peripheral portion since the Si pillar 33 serves as the supporter for the second insulating layer 26aa, the third insulating layer 28aa, and the third material layer 29aa in the memory region. In this case, in the step in FIGS. 5IA to 5ID, it is necessary to form the TiN layer 25A to be connected to the plate line PL and the TiN layer 27A to be connected to the word line WL by photolithography and RIE in the memory region. In this case, only a word line WL portion is subjected to etching by RIE, and thereby TiN layers to be connected to the plate line PL are formed to be continuous between memory cells. Also in this structure, memory operations can be performed.

The HfO₂ layers 36a and 36b that serve as gate insulating layers may be a single material layer or a plurality of material layers. In addition, a SiO₂ layer formed by oxidizing the outermost surface of the Si pillar 33 may be used in part or all of the gate insulating layers.

The TiN layers 25A and 27A that serve as gate conductor layers may be a single layer of another conductor material or a plurality of layers of other conductor materials. In addition, although the TiN layers 25A and 27A that serve as gate conductor layers are formed after the Si pillar 33 is formed, the TiN layers 25A and 27A that serve as gate conductor layers may be formed first, and the Si pillar 33 may be formed later.

The SiO₂ layer 22a in the outer region may be another insulating layer or another material layer.

Although the polishing by CMP is stopped at the surface of the first insulating layer 24 in FIGS. 5IA to 5ID, the polishing may be stopped at the surface of the mask insulating layer 23 or the surface of the SiO₂ layer 22a.

In FIGS. 5KA to 5KD, the N⁺ layer 21 may also be formed by making the donor impurity diffuse to a bottom portion of the Si pillar 33 by heat treatment in any step before the step in FIGS. 5KA to 5KD. In addition, an N⁺ layer may be formed on the top portion of the Si pillar 33 by heat treatment, low-temperature plasma doping, or the like before or after the N⁺ layer 39 is formed. If the N⁺ layer is formed on the top portion of the Si pillar 33, the N⁺ layer 39 may be omitted. Furthermore, since the N⁺ layer 21 is an impurity layer that is formed under the Si pillar 33 and that is connected to the source line SL of the memory cell in FIGS. 5AA to 5DA, the N⁺ layer 21 may be part of the memory region peripheral portion in the drawings or may be omitted. Furthermore, for example, a tungsten (W) layer may be embedded in the N⁺ layer 21 around the Si pillar 33.

Formation of the structure including the single TiN layer 25A to be connected to the plate line PL and the single TiN layer 27A to be connected to the word line WL has been described with reference to FIGS. 5AA to 5KD. However, each or one of the TiN layer 25A and the TiN layer 27A may be divided into a plurality of parts in the vertical direction. Alternatively, each or one of the TiN layer 25A and the TiN layer 27A may be divided into a plurality of parts also in plan view. In this case, dynamic flash memory operations can be performed by driving, synchronously or asynchronously, divided conductor layers connected to the plate line PL or the word line WL. In addition, the N⁺ layer 21 may be connected to the bit line BL, and the N⁺ layer 39 may be connected to the source line SL. Also in this case, normal dynamic flash memory operations can be performed.

This embodiment offers the following features.

### First Feature

When the dynamic flash memory cell performs a write or read operation, the voltage of the word line WL swings. At this time, the plate line PL has a function of decreasing the capacitive coupling ratio between the word line WL and the channel region 7a. As a result, the influence of a change in the voltage of the channel region 7a when the voltage of the word line WL swings can be significantly suppressed. This leads to an increase in the operation margin of the dynamic flash memory cell. In the manufacturing method of this dynamic flash memory, as illustrated in FIGS. 5CA to 5KD, the first insulating layer 24, the first material layer 25, the second insulating layer 26, the second material layer 27, the third insulating layer 28, and the third material layer 29, which are formed to be continuous from the memory region to an upper portion of the SiO₂ layer 22a in the outer region are polished by CMP such that the surfaces thereof are at the same level as the surface of the first insulating layer 24 on the SiO₂ layer 22a, and then, the first material layer 25aa and the second material layer 27aa are removed to form the TiN layer 25A to be connected to the plate line PL and the TiN layer 27A to be connected to the word line WL. Thus, in the memory region, terminals of the TiN layer 25A and the TiN layer 27A, which are separated from each other in the vertical direction, are formed on the same plane in the memory region peripheral portion. Thus, the TiN layers 25A and 27A can be connected to the metal wiring layers 42 and 50 without any intermediate connection portion therebetween. Furthermore, since the TiN layers 25A and 27A are connected to the metal wiring layers 42 and 50 on the same plane, the manufacturing method is simple.

### Second Feature

As illustrated in FIGS. 5HA to 5HD, in the memory region peripheral portion, the insulating layers 35a and 35b formed on the side surfaces of the holes 25b and 27b, the second insulating layer 26aa, the third insulating layer 28aa, and the third material layer 29aa in the direction perpendicular to the line X-X′ serve as supporters for the second insulating layer 26aa, the third insulating layer 28aa, and the third material layer 29aa that are suspended. This can prevent defects in later steps, such as damage or falling of the second insulating layer 26aa, the third insulating layer 28aa, and the third material layer 29aa.

### Second Embodiment

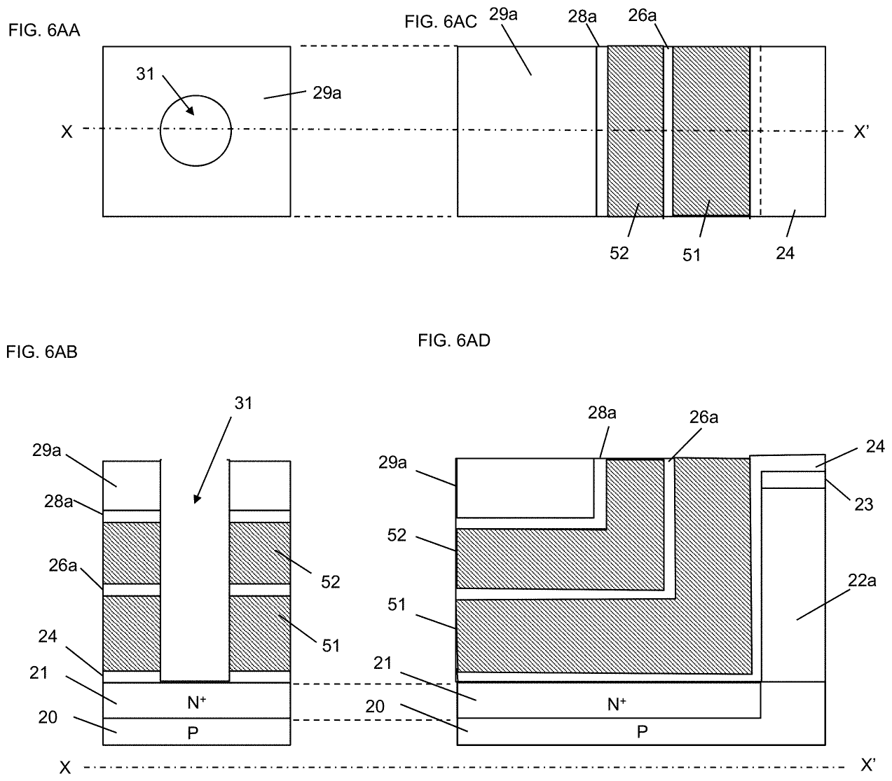

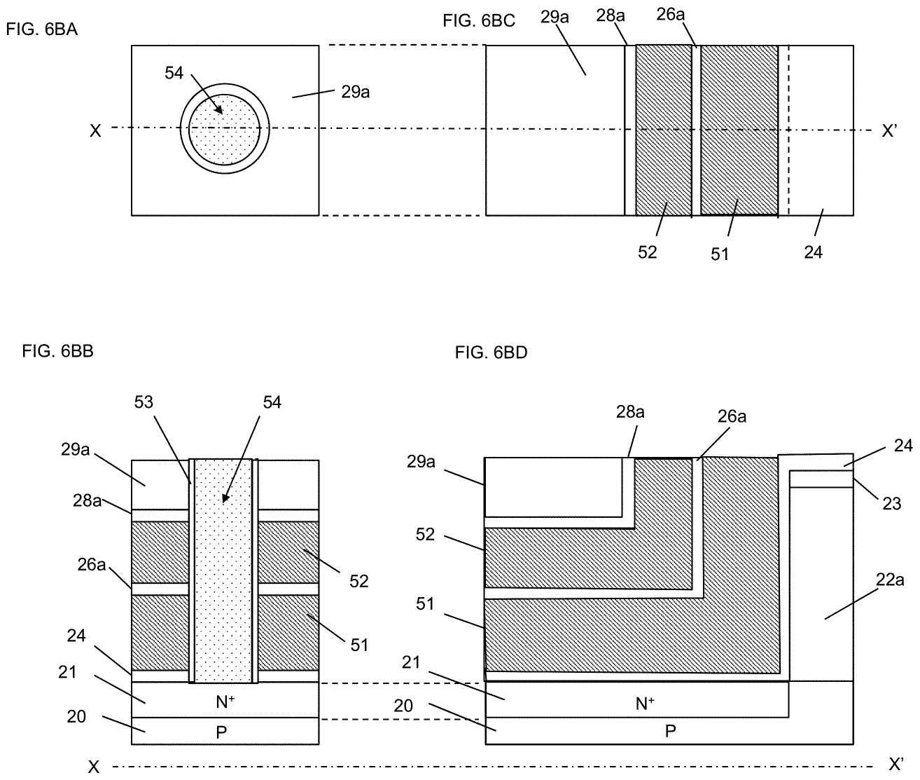

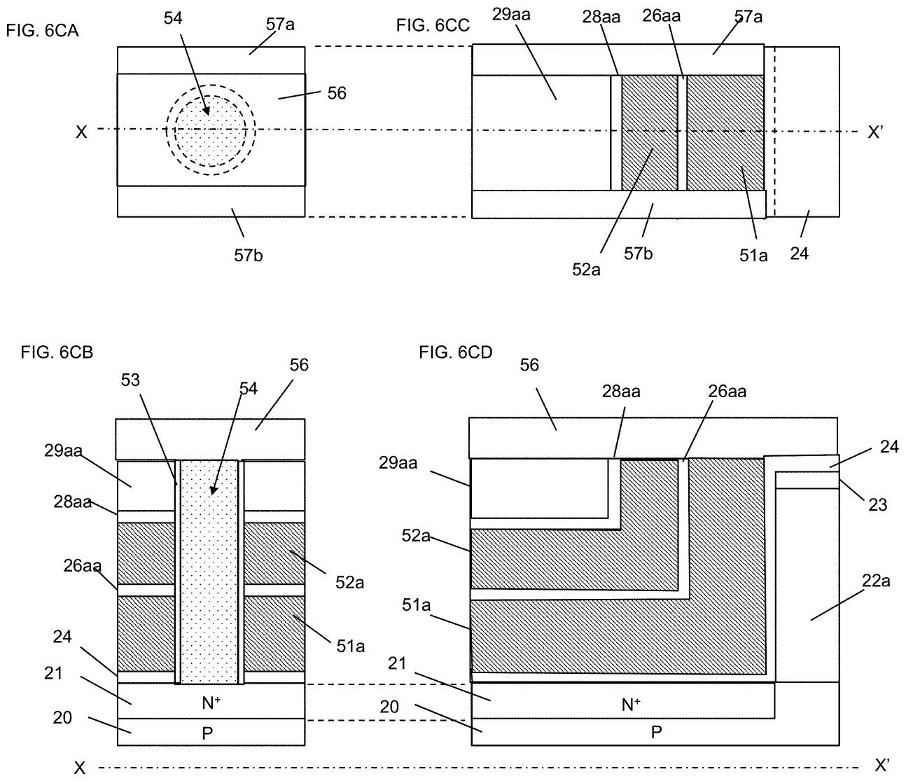

A manufacturing method of a semiconductor memory device according to a second embodiment will be described with reference to FIGS. 6AA to 6CD. Among FIGS. 6AA to 6CD, FIGS. 6AA, 6BA, and 6CA are plan views of a single memory cell of the semiconductor memory device, and FIGS. 6AC, 6BC, and 6CC are plan views for cell wiring connection in a memory region peripheral portion and an outer region. FIGS. 6AB, 6BB, and 6CB are sectional views, and FIGS. 6AD, 6BD, and 6CD are sectional views for cell wiring connection in the memory region peripheral portion and the outer region, taken along line X-X′ in FIGS. 6AA and 6AC, 6BA and 6BC, and 6CA and 6CC, respectively. A large number of such memory cells are arranged two-dimensionally in the memory device.

Substantially the same steps as those in FIGS. 5AA to 5ED are performed. As illustrated in FIGS. 6AA to 6AD, in these steps, instead of the first material layer 25a and the second material layer 27a surrounding the hole 31 in FIGS. 5EA to 5ED, TiN layers 51 and 52 that serve as gate conductor layers are formed. In the memory region peripheral portion, the TiN layers 51 and 52 are flush with the first insulating layer 24 on the SiO₂ layer 22a.

Subsequently, as illustrated in FIGS. 6BA to 6BD, a HfO₂ layer 53 that serves as a gate insulating layer is formed on the inner wall of the hole 31. Then, a Si pillar 54 is formed by epitaxial crystal growth inside the hole 31.

Subsequently, as illustrated in FIGS. 6CA to 6CD, as in the step illustrated in FIGS. 5GA to 5GD, a mask material layer 56 is formed. In plan view, the mask material layer 56 covers the Si pillar 54 and extends in the line X-X′ direction to reach the memory region peripheral portion and the outer region. Then, by using the mask material layer 56 as an etching mask, the third material layer 29a, the third insulating layer 28a, the TiN layer 52, the second insulating layer 26a, and the TiN layer 51 are etched by RIE to form the third material layer 29aa, the third insulating layer 28aa, a TiN layer 52a, the second insulating layer 26aa, and a TiN layer 51a. Then, insulating layers 57a and 57b are formed and embedded in spaces on side surfaces of the third material layer 29aa, the third insulating layer 28aa, the TiN layer 52a, the second insulating layer 26aa, and the TiN layer 51a in the direction perpendicular to the line X-X′. Then, substantially the same steps as those in FIGS. 5IA to 5KD are performed. Thus, a semiconductor memory device is formed on the P-layer substrate 20.

This embodiment offers the following features.

This embodiment does not include a step of forming the holes 25a and 27b and embedding the HfO₂ layers 36a and 36b and the TiN layers 25A and 27A in the holes 25b and 27b unlike in the first embodiment. Thus, the insulating layers 57a and 57b do not have a function as a supporter for the second insulating layer 26aa, the third insulating layer 28aa, and the third material layer 29aa that are suspended, unlike the insulating layers 35a and 36b in the first embodiment. This can simplify the manufacturing steps in this embodiment.

### Third Embodiment

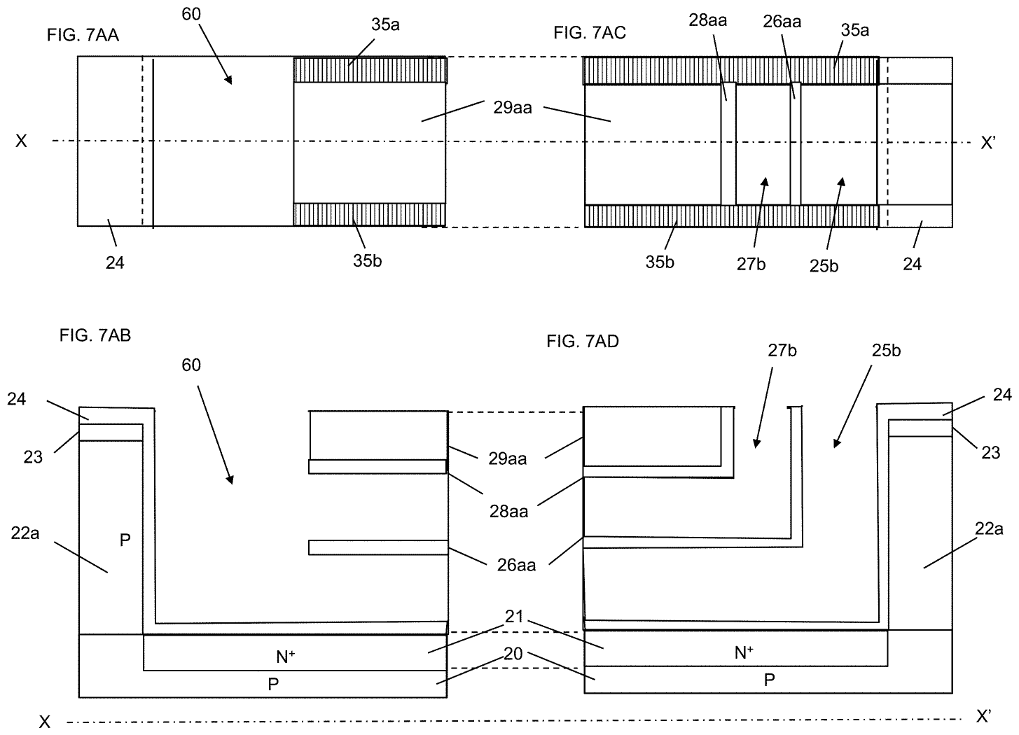

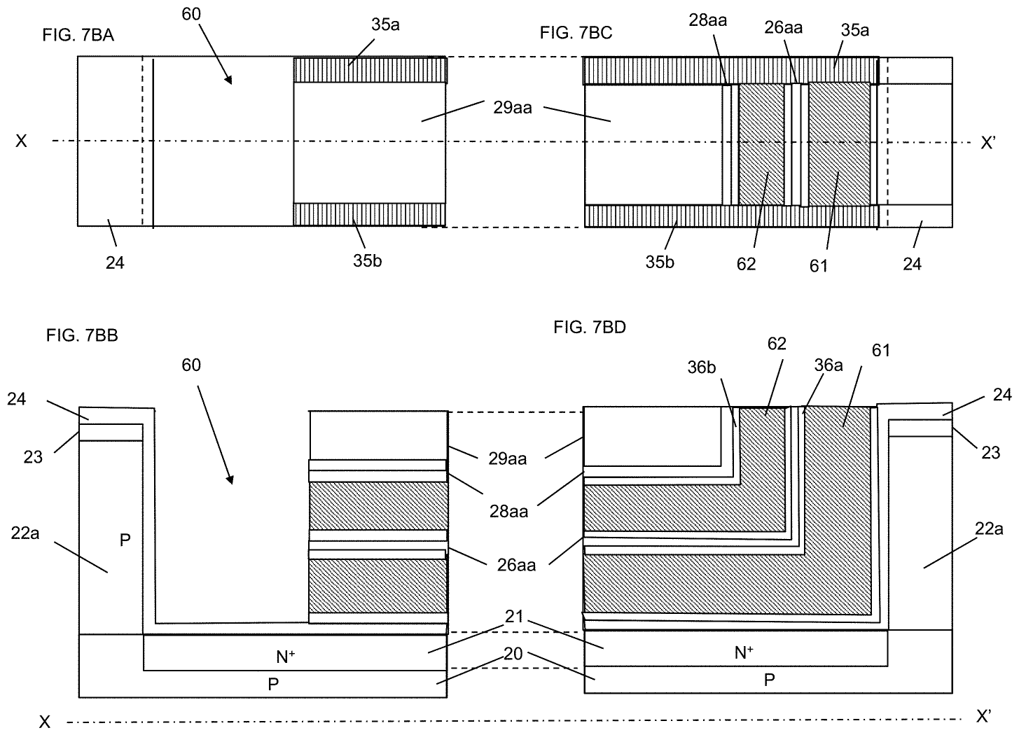

A manufacturing method of a semiconductor memory device according to a third embodiment will be described with reference to FIGS. 7AA to 7BD. Among FIGS. 7AA to 7BD, FIGS. 7AA and 7BA are plan views of a memory region peripheral portion and an outer region of the semiconductor memory device on one side, and FIGS. 7AC and 7BC are plan views of the memory region peripheral portion and the outer region. FIGS. 7AB and 7BB are sectional views of the memory region peripheral portion and the outer region on one side, and FIGS. 7AD and 7BD are sectional views of the memory region peripheral portion and the outer region, taken along line X-X′ in FIGS. 7AA and 7AC and FIGS. 7BA and 7BC, respectively. The memory cell illustrated in FIG. 5HA is provided between FIG. 7AA and FIG. 7AC and between FIG. 7BA and FIG. 7BC. In addition, the memory cell illustrated in FIG. 5HB is provided between FIG. 7AB and FIG. 7AD and between FIG. 7BB and FIG. 7BD. A large number of such memory cells are arranged two-dimensionally in the memory device.

Substantially the same steps as those in FIGS. 5AA to 5HD are performed. As illustrated in FIGS. 7AA to 7AD, as in FIGS. 5HA to 5HD, in the memory region peripheral portion and the outer region illustrated in FIGS. 7AC and 7AD, the holes 25b and 27b are continuous from the memory region to the memory region peripheral portion in the horizontal direction and bend in the vertical direction to be exposed in the memory region peripheral portion. In addition, the insulating layers 35a and 35b serve as supporters for the second insulating layer 26aa, the third insulating layer 28aa, and the third material layer 29aa that are suspended. Furthermore, in the memory region peripheral portion on the other side on the line X-X′ viewed from FIGS. 7AC and 7AD, as illustrated in FIGS. 7AA and 7AB, the holes 25b and 27b do not bend in the vertical direction unlike in FIGS. 7AC and 7AD. Thus, a hole 60 having a larger volume is formed. Then, a TiN layer (not illustrated) is embedded in the holes 25b, 27b, and 60.

Subsequently, as illustrated in FIGS. 7BA to 7BD, part of the TiN layer in the hole 60 is removed to form TiN layers 61 and 62. After an insulating layer (not illustrated) is embedded in the hole 60, substantially the same steps as those in FIGS. 5IA to 5KD are performed. Thus, a semiconductor memory device is formed on the P-layer substrate 20.

This embodiment offers the following features.

As illustrated in FIGS. 7BA to 7BD, unlike in the holes 25b and 27b illustrated in FIGS. 7BC and 7BD, in the hole 60 illustrated in FIGS. 7BA and 7BB, the second insulating layer 26aa does not have a portion that bends in the vertical direction. Thus, the hole 60 does not include the second insulating layer 26aa and has a large volume. As a result, the TiN layers 25A and 27A to be formed later can be embedded uniformly.

### OTHER EMBODIMENTS

In FIG. 1, the gate length of the first gate conductor layer 5a is made greater than the gate length of the second gate conductor layer 5b so that the gate capacitance of the first gate conductor layer 5a connected to the plate line PL can be greater than the gate capacitance of the second gate conductor layer 5b connected to the word line WL. However, instead of making the gate length of the first gate conductor layer 5a greater than the gate length of the second gate conductor layer 5b, the thickness of the first gate insulating layer 4a may be made smaller than the thickness of the second gate insulating layer 4b. Alternatively, the permittivity of the first gate insulating layer 4a may be made higher than the permittivity of the second gate insulating layer 4b. Furthermore, by using any of the lengths of the first gate conductor layer 5a and the second gate conductor layer 5b, and the thickness and permittivity of the first gate insulating layer 4a and the second gate insulating layer 4b in combination, the gate capacitance of the first gate conductor layer 5a may be made greater than the gate capacitance of the second gate conductor layer 5b. The same applies to the other embodiments.

In FIG. 1, the vertical-direction length of the first gate conductor layer 5a connected to the plate line PL is made greater than the vertical-direction length of the second gate conductor layer 5b connected to the word line WL so that C_{PL}>C_{WL} can be satisfied. However, addition of the plate line PL suffices to decrease the capacitive coupling ratio (C_{WL}/(C_{PL}+C_{WL}+C_{BL}+C_{SL})) of the word line WL to the channel region 7a. As a result, the potential change ΔV_{FB} of the channel region 7a of the floating body decreases. The same applies to the other embodiments.

The Si pillar 2 has a round shape in plan view in FIG. 1. However, the Si pillar 2 may have, for example, an elliptic shape or a shape elongated in one direction instead of a round shape. The same applies to the other embodiments.

In FIG. 1, an N-type impurity layer or a P-type impurity layer having a different acceptor impurity concentration may be provided between the N⁺ layer 3a and the P layer 7. In addition, an N-type impurity layer or a P-type impurity layer may be provided between the N⁺ layer 3b and the P layer 7. The same applies to the other embodiments.

The N⁺ layers 3a and 3b in FIG. 1 may be formed of Si or other semiconductor material layers containing a donor impurity. The N⁺ layer 3a and the N⁺ layer 3b may be formed of different semiconductor material layers. The same applies to the other embodiments.

Si pillars, each of which is the Si pillar 33 illustrated in FIGS. 5FA to 5KD, may be arranged two-dimensionally in a square lattice or in a diagonal lattice. If the Si pillars are disposed in a diagonal lattice, the Si pillars connected to a single word line may be disposed in a zigzag pattern or a serrated pattern in which each segment is constituted by a plurality of Si pillars. The same applies to the other embodiments.

Instead of the P-layer substrate 20 in FIGS. 5AA to 5KD, SOI, a multilayer well, or a conductor layer may be used. The same applies to the other embodiments.

FIG. 1 illustrates an example in which each of the first gate conductor layer 5a and the second gate conductor layer 5b is formed of a single conductor material layer. However, each of the first gate conductor layer 5a and the second gate conductor layer 5b may be formed of a plurality of conductor layers in the vertical direction. If each of the first gate conductor layer 5a and the second gate conductor layer 5b is formed of a plurality of conductor material layers, an insulating layer may be provided between the conductor material layers. For example, by making the thicknesses of these conductive material layers equal, the TiN layers 25A and 27A in FIGS. 5GA to 5GD can be embedded uniformly, which is advantageous.

In addition, the dynamic flash memory operations are performed also in a structure in which the polarities of the conductivity types of the N⁺ layers 3a and 3b and the P layer 7 in FIG. 1 are reversed. In this case, the majority carriers in the Si pillar 2 are electrons. Therefore, a group of electrons generated by impact ionization is stored in the channel region 7a, and the “1” state is set. The same applies to FIGS. 5AA to 5KD and the like.

The insulating layers 35a and 35b formed on the side surfaces of the third material layer 29aa, the third insulating layer 28aa, the second material layer 27aa, the second insulating layer 26aa, and the first material layer 25aa in the direction perpendicular to the line X-X′ in FIGS. 5GA to 5GD may be formed only in the memory region peripheral portion since the Si pillar 33 serves as the supporter for the second insulating layer 26aa, the third insulating layer 28aa, and the third material layer 29aa in the memory region. In addition, the insulating layers 35a and 35b may also be omitted in the memory region peripheral portion in a region including the third material layer 29aa, as long as an adjacent Si pillar 33 in the memory region in plan view can support the second insulating layer 26aa, the third insulating layer 28aa, and the third material layer 29aa. The same applies to the other embodiments.

Various embodiments and modifications of the present invention are possible without departing from the broad spirit and scope of the present invention. The embodiments described above are illustrative examples of the present invention and do not limit the scope of the present invention. The embodiments and modifications can be appropriately combined. Furthermore, some of constituent features of the above embodiments may be omitted as required, and such embodiments still fall within the technical idea of the present invention.

According to the semiconductor memory device and the manufacturing method of the semiconductor memory device according to the embodiments of the present invention, a high-density and high-performance semiconductor memory device can be obtained.

What is claimed is:

1. A manufacturing method of a semiconductor memory device that performs a data retention operation and a data erase operation, the data retention operation being an operation in which voltages to be applied to a first gate conductor layer, a second gate conductor layer, a first impurity layer, and a second impurity layer are controlled to retain, inside a semiconductor pillar, a group of holes or electrons that are generated by an impact ionization phenomenon or a gate induced drain leakage current and that serve as majority carriers in the semiconductor pillar, and the data erase operation being an operation in which the voltages to be applied to the first gate conductor layer, the second gate conductor layer, the first impurity layer, and the second impurity layer are controlled to discharge, from the semiconductor pillar, the group of holes or electrons that serve as majority carriers in the semiconductor pillar, the manufacturing method comprising:
a step of defining, on a substrate, a memory region in which a plurality of semiconductor pillars each of which is the semiconductor pillar are formed two-dimensionally, a first memory region peripheral portion that is on an outer side of the memory region, and an outer region that is on an outer side of and is adjacent to the first memory region peripheral portion;
a step of forming, on the substrate in the outer region, a peripheral material layer having
an upper surface at a position higher than an upper surface of the first memory region peripheral portion, and
a step-like shape at a boundary with the first memory region peripheral portion;
a step of forming, on the substrate in the memory region, the first impurity layer and a first insulating layer;
a step of forming, in the memory region and the first memory region peripheral portion and on the peripheral material layer, from a bottom, the first gate conductor layer, a second insulating layer, the second gate conductor layer, and a third insulating layer such that the first gate conductor layer, the second insulating layer, the second gate conductor layer, and the third insulating layer have a shape that is substantially same as the step-like shape between the first memory region peripheral portion and the peripheral material layer and that at least an upper surface of the third insulating layer in the memory region is positioned lower than the upper surface of the peripheral material layer;
a step of making, in the first memory region peripheral portion, the first gate conductor layer and the second gate conductor layer bend upward in a vertical direction along the step-like shape, making the first gate conductor layer and the second gate conductor layer have upper surfaces at a same position, and making the upper surfaces of the first gate conductor layer and the second gate conductor layer positioned close to the upper surface of the peripheral material layer; and
a step of forming a first metal wiring layer to be connected to the first gate conductor layer and a second metal wiring layer to be connected to the second gate conductor layer in the first memory region peripheral portion.

2. The manufacturing method of a semiconductor memory device according to claim 1, further comprising:
a step of, after forming the peripheral material layer and the first insulating layer, forming, from the bottom, a first material layer, the second insulating layer, a second material layer, and the third insulating layer such that the first material layer, the second insulating layer, the second material layer, and the third insulating layer cover the memory region, the first memory region peripheral portion, and the outer region;
a step of polishing an entirety of the memory region, the first memory region peripheral portion, and the outer region such that, in the first memory region peripheral portion, upper surfaces of the first material layer, the second insulating layer, the second material layer, and the third insulating layer, which extend in the vertical direction, are positioned close to the upper surface of the peripheral material layer;
a step of forming, on the first impurity layer in the memory region, a first hole penetrating through the third insulating layer, the second material layer, the second insulating layer, the first material layer, and the first insulating layer in the vertical direction;
a step of forming the semiconductor pillar embedded in the first hole;
a step of removing the first material layer to form a second hole and removing the second material layer to form a third hole;
a step of forming a first gate insulating layer inside the second hole and forming a second gate insulating layer inside the third hole; and
a step of forming a first conductor layer that is embedded in the second hole to serve as the first gate conductor layer and a second conductor layer that is embedded in the third hole to serve as the second gate conductor layer.

3. The manufacturing method of a semiconductor memory device according to claim 2, further comprising:
a step of, before forming the second hole and the third hole, forming a fourth insulating layer that is connected to the second insulating layer and the third insulating layer in the first memory region peripheral portion and that extends from an upper surface of the first insulating layer in the vertical direction such that an upper surface of the fourth insulating layer is positioned close to the upper surface of the peripheral material layer.

4. The manufacturing method of a semiconductor memory device according to claim 1, further comprising:
a step of, after forming the peripheral material layer and the first insulating layer, forming, from the bottom, a third conductor layer that is to serve as the first gate conductor layer, the second insulating layer, a fourth conductor layer that is to serve as the second gate conductor layer, and the third insulating layer such that the third conductor layer, the second insulating layer, the fourth conductor layer, and the third insulating layer cover the memory region, the first memory region peripheral portion, and the outer region;
a step of polishing an entirety of the memory region, the first memory region peripheral portion, and the outer region such that, in the first memory region peripheral portion, upper surfaces of the third conductor layer, the second insulating layer, the fourth conductor layer, and the third insulating layer, which extend in the vertical direction, are positioned close to the upper surface of the peripheral material layer;
a step of forming, in the memory region, a fourth hole penetrating through the third insulating layer, the fourth conductor layer, the second insulating layer, the third conductor layer, and the first insulating layer; and
a step of forming a third gate insulating layer that covers an inner wall of the fourth hole and the semiconductor pillar that is in contact with the first impurity layer.

5. The manufacturing method of a semiconductor memory device according to claim 1, wherein
in a second memory region peripheral portion opposite to the first memory region peripheral portion with the memory region therebetween in plan view, the second insulating layer that bends from a horizontal direction to the vertical direction is not formed.

6. The manufacturing method of a semiconductor memory device according to claim 1, wherein
if one of the first impurity layer and the second impurity layer is connected to a source line, another of the first impurity layer and the second impurity layer is connected to a bit line, and
if one of the first gate conductor layer and the second gate conductor layer is connected to a plate line, another of the first gate conductor layer and the second gate conductor layer is connected to a word line.

7. The manufacturing method of a semiconductor memory device according to claim 1, further comprising:
a step of forming a third material layer on the third insulating layer;
a step of removing part of the third material layer to expose a top portion of the semiconductor pillar; and
a step of forming the second impurity layer that covers the exposed top portion of the semiconductor pillar or that is inside the top portion.

8. The manufacturing method of a semiconductor memory device according to claim 1, wherein
the third insulating layer is formed of a plurality of material layers.

9. A semiconductor memory device in which each of memory cells performs a data retention operation and a data erase operation, the data retention operation being an operation in which voltages to be applied to a first gate conductor layer, a second gate conductor layer, a first impurity layer, and a second impurity layer are controlled to retain, inside a semiconductor pillar, a group of holes or electrons that are generated by an impact ionization phenomenon or a gate induced drain leakage current and that serve as majority carriers in the semiconductor pillar, and the data erase operation being an operation in which the voltages to be applied to the first gate conductor layer, the second gate conductor layer, the first impurity layer, and the second impurity layer are controlled to discharge, from the semiconductor pillar, the group of holes or electrons that serve as majority carriers in the semiconductor pillar, the semiconductor memory device comprising:
on a substrate, a memory region in which a plurality of semiconductor pillars each of which is the semiconductor pillar are formed two-dimensionally, a first memory region peripheral portion that is on an outer side of the memory region, and an outer region that is on an outer side of and is adjacent to the first memory region peripheral portion;
on the substrate in the outer region, a peripheral material layer having
an upper surface at a position higher than an upper surface of the first memory region peripheral portion, and
a step-like shape at a boundary with the first memory region peripheral portion;
on the substrate in the memory region and the first memory region peripheral portion, the first impurity layer and a first insulating layer; and
a first metal wiring layer to be connected to the first gate conductor layer and a second metal wiring layer to be connected to the second gate conductor layer in the first memory region peripheral portion, wherein
in the memory region and the first memory region peripheral portion and on the peripheral material layer, from a bottom, the first gate conductor layer, a second insulating layer, the second gate conductor layer, and a third insulating layer are formed such that the first gate conductor layer, the second insulating layer, the second gate conductor layer, and the third insulating layer have a shape that is substantially same as the step-like shape between the first memory region peripheral portion and the peripheral material layer and that at least an upper surface of the third insulating layer in the memory region is positioned lower than the upper surface of the peripheral material layer, and
in the first memory region peripheral portion, the first gate conductor layer and the second gate conductor layer bend upward in a vertical direction along the step-like shape, the first gate conductor layer and the second gate conductor layer have upper surfaces at a same position, and the upper surfaces of the first gate conductor layer and the second gate conductor layer are positioned close to the upper surface of the peripheral material layer.

10. The semiconductor memory device according to claim 9, further comprising:
a fourth insulating layer that is connected to the second insulating layer and the third insulating layer in the first memory region peripheral portion and that extends from an upper surface of the first insulating layer in the vertical direction such that an upper surface of the fourth insulating layer is positioned close to the upper surface of the peripheral material layer.

11. The semiconductor memory device according to claim 9, wherein
a second memory region peripheral portion opposite to the first memory region peripheral portion with the memory region therebetween in plan view does not have the second insulating layer that bends from a horizontal direction to the vertical direction.

12. The semiconductor memory device according to claim 9, wherein
if one of the first impurity layer and the second impurity layer is connected to a source line, another of the first impurity layer and the second impurity layer is connected to a bit line, and
if one of the first gate conductor layer and the second gate conductor layer is connected to a plate line, another of the first gate conductor layer and the second gate conductor layer is connected to a word line.

13. The semiconductor memory device according to claim 12, wherein
the first gate conductor layer is connected to laterally and longitudinally adjacent semiconductor pillars in plan view.

14. The semiconductor memory device according to claim 9, wherein
at least one of the first gate conductor layer and the second gate conductor layer is divided into a plurality of parts in plan view.

15. The semiconductor memory device according to claim 9, wherein
at least one of the first gate conductor layer and the second gate conductor layer is divided into a plurality of parts in a direction perpendicular to the substrate.
